(19) United States
(12) Patent Application Publication
(10) Pub. No.: US 2012/0043983 A1
(43) Pub. Date: Feb. 23, 2012

(54) INSPECTION DEVICE OF SEMICONDUCTOR INTEGRATED CIRCUIT, INSPECTION METHOD OF SEMICONDUCTOR INTEGRATED CIRCUIT, AND CONTROL PROGRAM OF INSPECTION DEVICE OF SEMICONDUCTOR INTEGRATED CIRCUIT

(75) Inventors: Nobuhiro SAWA, Shiga (JP); Toru KUME, Kanagawa (JP)

(73) Assignee: RENESAS ELECTRONICS CORPORATION, Kanagawa (JP)

(21) Appl. No.: 13/212,800

(22) Filed: Aug. 18, 2011

(30) Foreign Application Priority Data
Aug. 23, 2010 (JP) 2010-185873

(51) Int. Cl. G01R 31/00

(52) U.S. Cl. 324/750.19

(57) ABSTRACT

An inspection device of a semiconductor integrated circuit includes a drive unit that moves a probe card back and forth and from side to side, a storage unit that stores arrangement of the semiconductor integrated circuit and a shape of the pads, and a control unit that controls the drive unit. The control unit controls the drive unit, performs an apex detection processing pressing the probe pin to the semiconductor integrated circuit, detecting positions of the probe pin where conduction is detected or not detected, and calculating coordinates of one apex of a inspection pad from detected positions, and calculates central coordinates of the inspection pad from information of the shape of the inspection pad based on the coordinates of the apex of the inspection pad. The drive unit presses the probe pin to the calculated central coordinates of the inspection pad to perform inspection.

### CROSS-REFERENCE TO RELATED APPLICATIONS

This application is based upon and claims the benefit of priority from Japanese patent application No. 2010-185873, filed on Aug. 23, 2010, the disclosure of which is incorporated herein in its entirety by reference.

### BACKGROUND

The present invention relates to an inspection device of a semiconductor integrated circuit, an inspection method of the semiconductor integrated circuit, and a control program of the inspection device of the semiconductor integrated circuit, and more specifically, to an inspection device of a semiconductor integrated circuit, an inspection method of the semiconductor integrated circuit, and a control program of the inspection device of the semiconductor integrated circuit using a probe card.

In recent years, a probe card needle and a test pad of a semiconductor device are aligned, in X/Y directions, by an operator using a camera. At this time, a needle tip of the probe card needs to be adjusted to the center of the pad. However, recent reduction in size of the pad due to a narrow pitch reduces the size of the pad in a screen. This requires high level of technique of operators, and tends to cause frequent contact failure between the test pad and the probe card.

Japanese Unexamined Patent Application Publication No. 2006-023229 discloses a technique for providing a probe card quality evaluation method, a probe card quality evaluation device, and a probe inspection method that achieve high contact property between a probe pin of a probe card and an electrode pad of a circuit element with high reproducibility.

The technique disclosed in Japanese Unexamined Patent Application Publication No. 2006-023229 will be described. FIG. 33 shows an example of an operation for moving probe pins. FIG. 34 is a flow chart showing an inspection method using a probe card. According to the technique disclosed in Japanese Unexamined Patent Application Publication No. 2006-023229, after the position of a support stage that fixes an IC chip is roughly adjusted, the probe pins are moved in a horizontal direction in accordance with a surface of the IC chip where electrode pads are formed. Then, positional coordinates of the support stage when the probe pin falls from the electrode pad are obtained.

The position of the point P₀ where all the probe pins 232 contact with the electrode pads varies among electrode pads. A contact test is performed from this state by moving all the probe pins 232 at certain pitches in the X direction, to thereby obtaining the coordinate position range in which all the probe pins 232 contact with the electrode pads. The coordinate positional range is calculated similarly for the Y direction as well. From thus-obtained coordinate positional ranges, positional coordinates in which all the probe pins 232 are arranged at the center of each pad are obtained. This enables excellent contact of the electrode pads with the probe pins with high reproducibility.

Meanwhile, International Patent Publication No. WO 2007-032077 discloses a technique that is capable of adjusting positions of an IC chip and a probe card with higher accuracy. The technique disclosed in International Patent Publication No. WO 2007-032077 takes images of an electrode pad of an IC chip and a needle tip of a probe, and enlarges the images that are taken. This allows an operator to perform alignment with higher accuracy. Further, the technique disclosed in International Patent Publication No. WO 2007-032077 extracts the shape of the electrode pad from the image of the electrode pad that is taken. The center of the electrode pad is specified from the shape of the electrode pad that is extracted. This allows an operator to achieve alignment of the probe card easier and with more accuracy.

Further, Japanese Unexamined Patent Application Publication No. 57-2539 discloses a technique capable of obtaining a center of an electrode pad. According to the technique disclosed in Japanese Unexamined Patent Application Publication No. 57-2539, an image of the electrode pad is taken, and x and y coordinates of the apex of the electrode pad are obtained from the image that is taken. Then, a middle point between the smallest value and the largest value of the x and y coordinates of the apex is obtained, which is set to the center of the electrode pad. In this way, the center of the electrode pad can be obtained even when a part of the electrode pad is deficient.

### SUMMARY

However, according to the technique disclosed in Japanese Unexamined Patent Application Publication No. 2006-023229, the conduction state between the pad and the probe needs to be searched in many locations, which takes time to determine the center of the pad. Further, probing is performed by moving the probe pin back and forth and from side to side. Since this operation is to detect the center of the pad, the center of the pad is damaged by probing. Thus, the pad may be judged as a failure when a normal semiconductor inspection is performed.

The techniques disclosed in International Patent Publication No. WO 2007-032077 and Japanese Unexamined Patent Application Publication No. 57-2539 detect coordinates of apices of the electrode pad from an image. However, an image analysis device is required to detect coordinates from the image. Further, since the size of the electrode pad has been decreasing in recent years, it is difficult to take an image of the electrode pad.

A first aspect of the present invention is an inspection device of a semiconductor integrated circuit including a drive unit that moves a probe card including a plurality of probe pins back and forth and from side to side, the respective probe pins corresponding to a plurality of pads connected to a plurality of terminals of a semiconductor, a storage unit that stores arrangement of the semiconductor integrated circuit and a shape of the plurality of pads connected to the plurality of terminals of the semiconductor, and a control unit that controls the drive unit based on the shape of the plurality of pads obtained from the storage unit. The control unit controls the drive unit, performs an apex detection processing and calculates central coordinates of the inspection pad from information of the shape of the inspection pad based on coordinates of one apex of the inspection pad. The inspection pad is a target to be inspected among the plurality of pads. The apex detection processing is detecting a position of the probe pin where conduction is detected and another position of the probe pin where conduction is not detected and calculating the coordinates of the apex of the inspection pad from detected positions. The drive unit presses the probe pin to the calculated central coordinates of the inspection pad based on the control by the control unit to perform inspection.

A second aspect of the present invention is an inspection method of a semiconductor integrated circuit including storing a shape of a plurality of pads connected to a plurality of terminals of the semiconductor integrated circuit and an arrangement of the semiconductor integrated circuit in a storage unit, controlling a drive unit to move a probe card back and forth and from side to side, performing an apex detection processing and calculating central coordinates of the inspection pad from information of the shape of the inspection pad based on coordinates of one apex of the inspection pad, and controlling the drive unit to press the probe pin to the calculated central coordinates of the inspection pad to perform inspection.

The probe card includes a plurality of probe pins. The respective probe pins corresponds to a plurality of inspection pads connected to the plurality of terminals of the semiconductor integrated circuit. The inspection pad is a target to be inspected among the plurality of pads. The apex detection processing is pressing the probe pin to the semiconductor integrated circuit, detecting a position of the probe pin where conduction is detected and another position of the probe pin where conduction is not detected, and calculating the coordinates of the apex of the inspection pad from detected positions.

According to the present invention, coordinates of diagonally opposite corners of the test pad are calculated, and the middle point of the two coordinates is calculated as central coordinates of the pad, thereby capable of obtaining positional information of the center of the pad in a short time and with high accuracy.

According to the present invention, it is possible to provide an inspection device of a semiconductor integrated circuit, an inspection method of the semiconductor integrated circuit, and a control program of an inspection device of the semiconductor integrated circuit that are capable of performing a conduction inspection of the semiconductor integrated circuit in a short time and with higher accuracy.

### BRIEF DESCRIPTION OF THE DRAWINGS

The above and other aspects, advantages and features will be more apparent from the following description of certain embodiments taken in conjunction with the accompanying drawings, in which:

FIG. 1 shows a semiconductor inspection device 1 according to a first embodiment;

FIG. 2A shows a concept of a test pad 18 of TAB according to the first embodiment;

FIG. 2B shows a tape 15 and the test pad 18 according to the first embodiment;

FIG. 3 is a flow chart showing an outline of a semiconductor inspection method according to the first embodiment;

FIG. 4 is a flow chart showing further detail of an operation of teaching according to the first embodiment;

FIG. 5 shows an outline of the test pad 18 and a diagonal vector according to the first embodiment;

FIG. 6 shows a concept of a method of detecting a middle point between upper left coordinates (PLU) and lower right coordinates (PRD) of a pad of an IC chip on a layout according to the first embodiment;

FIG. 7 shows a state in which a probe card 16 is adjusted with respect to an IC chip 14 for connection according to the first embodiment;

FIG. 8 is a flow chart showing a method of detecting pad upper left coordinates according to the first embodiment;

FIG. 9 shows one example of a method of checking conduction according to the first embodiment;

FIG. 10 is a flow chart showing a method of checking an upper left apex of the test pad 18 according to the first embodiment;

FIGS. 11A and 11B each shows positions of the test pad 18 and a needle tip of a probe needle 17 according to the first embodiment;

FIG. 12 shows the accuracy of PLU according to the first embodiment;

FIG. 13 is a flow chart showing a method of obtaining pad lower right coordinates (PRD) according to the first embodiment;

FIG. 14 is a flow chart showing a method of processing for detecting a lower right apex according to the first embodiment;

FIG. 15 shows a state in which the accuracy of PLU increases according to the first embodiment;

FIG. 16 shows positions of the test pad 18 on which teaching is executed and the IC chip 14 on the layout according to the first embodiment of the present invention;

FIG. 17 shows a semiconductor inspection device 31 according to a second embodiment;

FIGS. 18A and 18B each shows a test pad 34 according to the second embodiment;

FIG. 19 shows positions of the test pad 34 and a needle tip of a probe needle 17 according to the second embodiment;

FIG. 20 shows a semiconductor wafer 32 according to the second embodiment;

FIGS. 21A and 21B each shows positions of a needle tip of the probe needle 17 and the test pad 34 according to the second embodiment;

FIG. 22 shows expectation values of the accuracy of pad center coordinates (PC) according to the second embodiment;

FIG. 23 shows test pads 34 of an IC chip 33 according to the second embodiment;

FIG. 24 is a flow chart showing a teaching method of a prober according to a third embodiment;

FIG. 25 is a flow chart showing a method of obtaining pad upper left coordinates (PLU) according to the third embodiment;

FIG. 26 is a flow chart showing processing for detecting an upper left apex according to the third embodiment;

FIG. 27 is a flow chart showing a method of obtaining pad lower right coordinates (PRD) according to the third embodiment;

FIG. 28 shows a flow chart for detecting a lower right apex according to the third embodiment;

FIG. 29 shows an outline of a selection of a teaching execution pad 34a according to the third embodiment;

FIG. 30 shows an error data analysis method regarding θ deviation according to the third embodiment;

FIG. 31 shows positions of a test pad and a probe needle 17 according to the third embodiment;

FIG. 32 shows one example of the error data analysis according to the third embodiment;

FIG. 33 shows one example of an operation for moving probe pins according to a related art; and

FIG. 34 is a flow chart showing a related inspection method using a probe card.

### DETAILED DESCRIPTION

### First Embodiment

Embodiments of the present invention will be described hereinafter with reference to the accompanying drawings. For the sake of convenience of description, the following description and the drawings are omitted and simplified as appropriate. In the first embodiment, storage may be performed not only with electromagnetic means but also with mechanical means, especially when results of program processing are stored after being mechanically adjusted by hand.

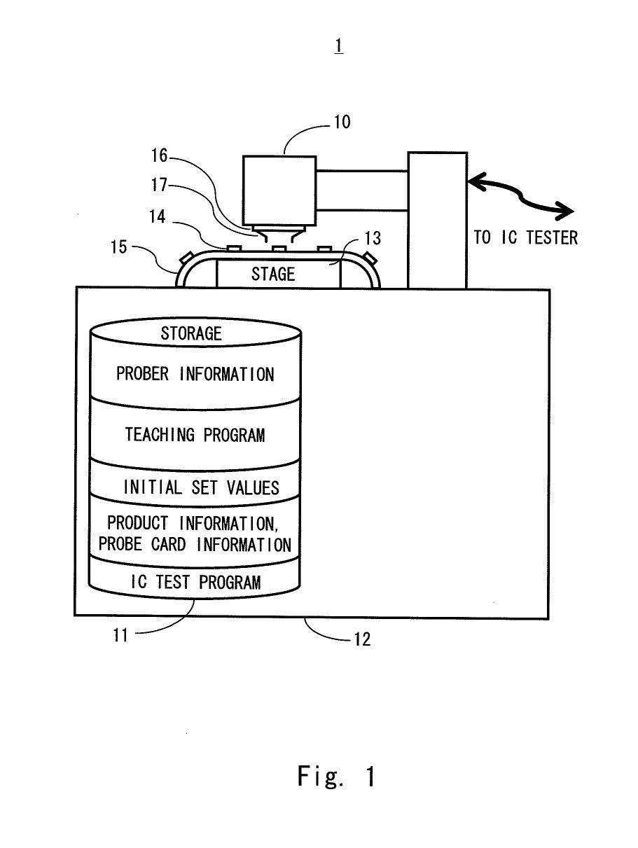

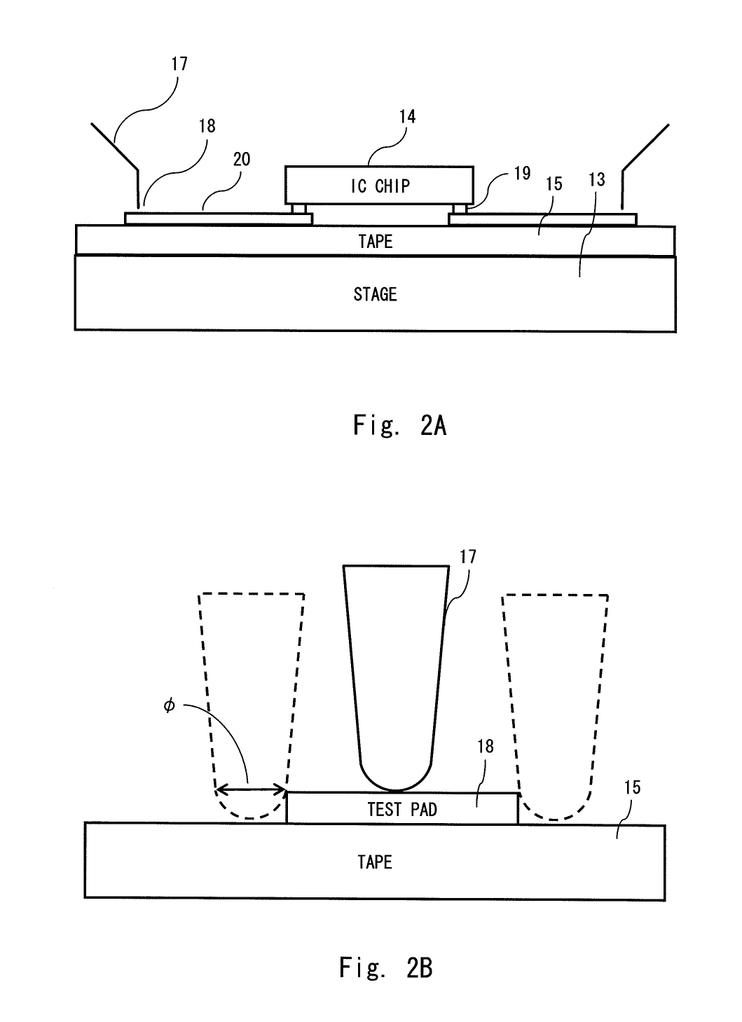

FIG. 1 is a diagram showing a semiconductor inspection device 1 according to the first embodiment of the present invention. The semiconductor inspection device 1 includes a station head 10, a storage 11, and a controller 12. The station head 10 moves a probe card 16 including a plurality of probe needles 17 back and forth and from side to side, the respective probe needles 17 corresponding to a plurality of test pads 18 (see FIG. 2) of an IC chip 14. The storage 11 stores locations of the IC chip and the shape of the test pads 18 of a plurality of terminals of the IC chip 14 contacted by the probe needles 17. The controller 12 controls the station head 10 based on the shape of the test pad 18 obtained from the storage 11.

The controller 12 controls the station head 10, presses the probe needle 17 to the test pad 18 to detect a conduction state of the test pad 18, and detects apex coordinates of the test pad 18 from the position of the probe needle 17 where a conduction state is detected and the position of the probe needle 17 where the conduction state is not detected. This operation is performed on at least one apex of the test pad 18. When one apex of the test pad 18 is detected, the central coordinates of the test pad 18 are calculated from the information of the shape of the test pad 18. The station head 10 presses the probe needle 17 to the central coordinates of the test pad 18 that are calculated based on the control by the controller 12 to check the conduction state of the semiconductor device.

Accordingly, the semiconductor inspection device according to the first embodiment detects the apex coordinates of the test pad, and calculates the central coordinates of the test pad using the information of the shape of the test pad from the apex coordinates that are detected. Thus, the central coordinates of the test pad can be obtained much easier compared with the related arts.

The semiconductor inspection device 1 according to the first embodiment will further be described. The station head 10 rotates the fixed probe card 16 in a horizontal direction or back and forth and from side to side, thereby ensuring an appropriate contact of the probe needle 17 to the IC chip 14 that is fixed to the stage 13.

The station head 10 further includes a wire that electrically connects the probe card 16 and an IC tester (not shown). This allows the station head 10 to transmit an output signal from the IC tester to the test pad 18 through the probe card needle 17 and to transmit an output signal from the test pad 18 to the IC tester.

The storage 11 stores prober information which is data specific to the semiconductor inspection device 1, product information of the IC chip 14 which is to be inspected, probe card information corresponding to the IC chip 14, a teaching program which is a program to adjust the positions of the test pad 18 and the probe card 16 of the semiconductor inspection device 1, a set value which is a result of the teaching program, and an IC test program. Note that a part of the set value which is the result of the teaching program may be stored in the semiconductor inspection device 1 by mechanical means.

The product information of the IC chip 14 includes pad size information (CW, LW), pad shape information, size information of the IC chip 14 that are required to calculate a diagonal vector D (see FIG. 5) described below.

The probe card information includes information of a size of a diameter φ of the probe needle tip required for calculating the diagonal vector D and physical information of the probe card required for calculating a margin vector δ.

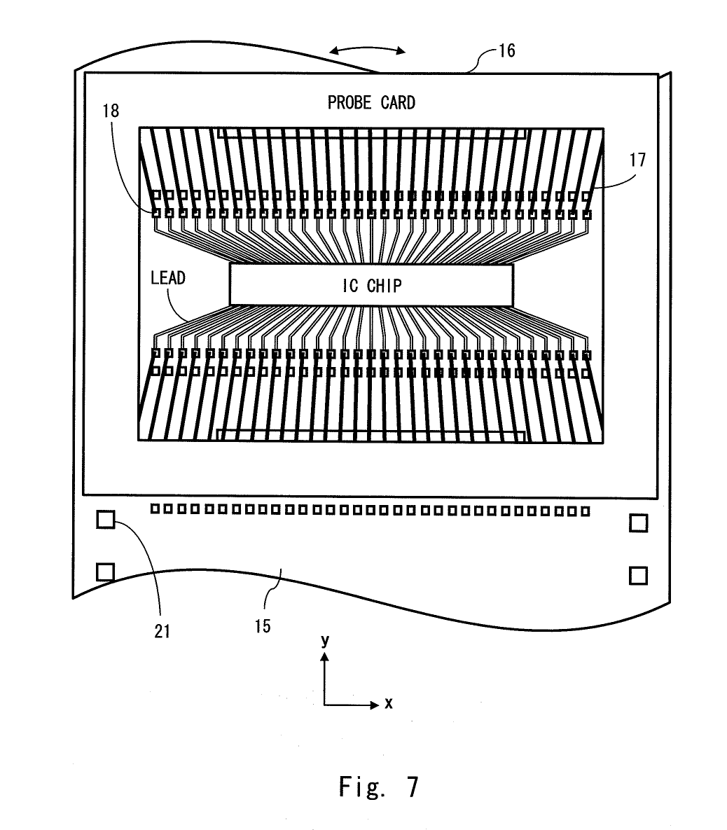

The controller 12 controls the station head 10 based on the information obtained from the storage 11. Further, the controller 12 moves one or both of the station head 10 and the stage 13 up and down, thereby electrically connecting the probe needle 17 to the test pad 18 (FIGS. 2A and 2B) on a tape 15, or disconnecting the probe needle 17 from the test pad 18. When the test of one IC chip 14 is completed, a tape is moved by sprocket holes 21 (see FIG. 7) receiving teeth of a sprocket (not shown), thereby setting the next IC chip 14 which is to be tested below the station head.

The controller 12 includes the storage 11, and includes a circuit set mainly including a microcomputer. The controller 12 controls the station head 10, the stage 13 and the like based on the program and the data loaded from the storage 11. Needless to say, the loading of the program and the data includes not only an actual data transfer but also mere recognition of an area on the storage 11 where various programs and data are stored.

The stage 13 fixes the tape 15 on which the IC chips 14 are mounted by vacuum suction or the like. In the first embodiment, the IC chip 14 and the probe card 16 are aligned by the movement of the station head 10. However, they may be aligned by the movement of the stage 13.

Further, the semiconductor inspection device 1 may receive and process a returned value from the IC tester as a result of executing the inspection program of the IC chip 14. Furthermore, the functions can be achieved in the similar way through the work by an operator who observes the result of the IC tester.

FIG. 2A shows a concept of the test pad 18 of TAB. The test pad 18 according to the first embodiment is of land type as shown in FIG. 2A. The test pad 18 may be provided on the tape surface with some thickness or may be provided in the same plane as the tape surface.

The IC chip 14 includes a bump 19 that is configured to be connected to a lead. A lead 20 provided on the tape 15 includes the bump 19 on one end, and the test pad 18 on the other end. Since the test pad 18 has the same thickness as the lead 20, the test pad 18 is formed on the tape 15 with some thickness.

FIG. 2B shows the tape 15 and the test pad 18. When the probe needle 17 contacts with the test pad 18, the probe needle 17 and the test pad 18 are conducted; when the needle tip does not contact with the test pad 18, the probe needle 17 and the test pad 18 are not conducted. Thus, the shape of the pad can be detected by detecting the conduction with the pad. The diameter of the probe needle 17 when the probe needle 17 somehow contacts with the test pad 18 (probe needle in the position shown by dotted lines in FIG. 2B) is denoted by a probe needle tip diameter φ.

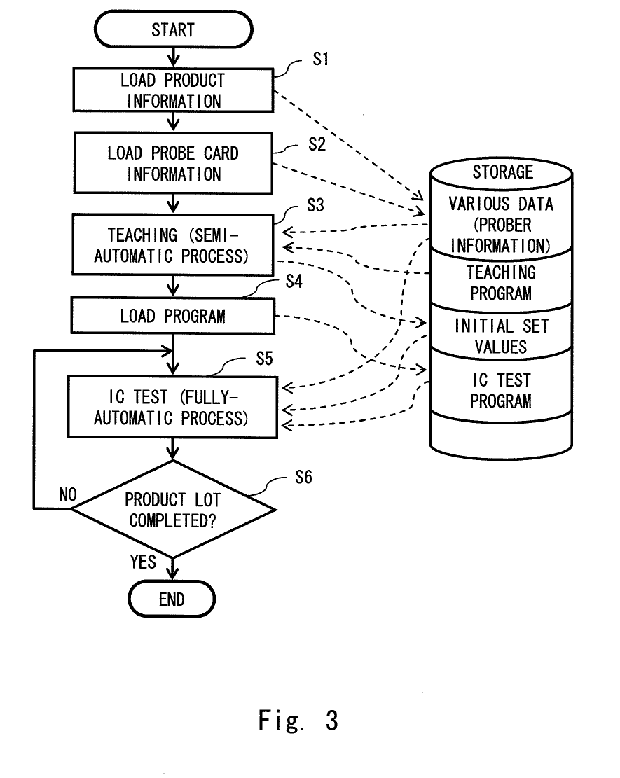

Next, an outline of the operation of the semiconductor inspection device 1 according to the first embodiment will be described. FIG. 3 is a flow chart showing an outline of the semiconductor inspection method according to the first embodiment. First, the controller 12 obtains product information (arrangement of the test pads 18 on the tape 15) from an external device and stores the product information in the storage 11 (step S1).

Next, probe card information (probe needle tip diameter φ (see FIG. 2B), and deviation amount of the needle tip at the time of probing which is the function of an overdrive amount) is obtained from an external device, and the obtained information is stored in the storage 11 (step S2). Now, the deviation amount of the needle tip at the time of probing is the amount of deviation of the needle tip of the probe needle 17 from the contacted coordinates when the probe needle 17 is pressed to the test pad 18.

Next, the teaching program, the product information, the probe card information, and the prober information (alignment accuracy or the like) originally included in the semiconductor inspection device 1 are loaded from the storage 11 to the controller 12.

Next, initial setting of the position of the station head 10 is roughly performed by hand, thereafter pad center coordinates (PC) are obtained by the teaching program. The initial set values are obtained from the pad center coordinates and are stored in the storage 11. This series of operations are called prober teaching (step S3). This process is a semi-automatic process in that the initial setting is performed by hand.

Next, an IC test program that corresponds to the product is externally loaded to the storage 11 (step S4). The initial set values, the product information, and the IC test program are loaded to the controller 12 from the storage 11, and the IC test is executed by fully-automatic process (step S5). The same products of the same lot (hereinafter referred to as product lot) do not require another teaching, but the IC test can be executed continuously (step S6).

Upon completion of the product lot, the semiconductor inspection of the present invention is ended (END). When another product lot is to be tested, the process starts from the first process (START) in the similar way.

Next, a method of obtaining the central coordinates of the test pad 18 of the semiconductor inspection device 1 according to the first embodiment will further be described.

The semiconductor inspection device 1 according to the first embodiment detects the coordinates of the apex of the test pad 18, and then calculates the coordinates of the center of the IC chip 14 using the information of the shape of the IC chip 14 stored in the storage 11.

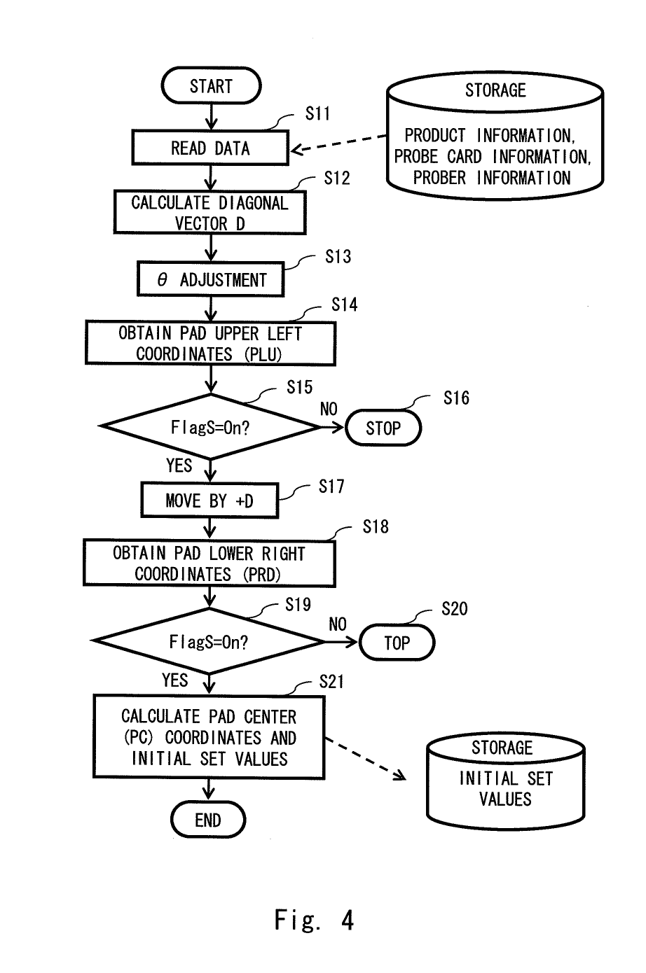

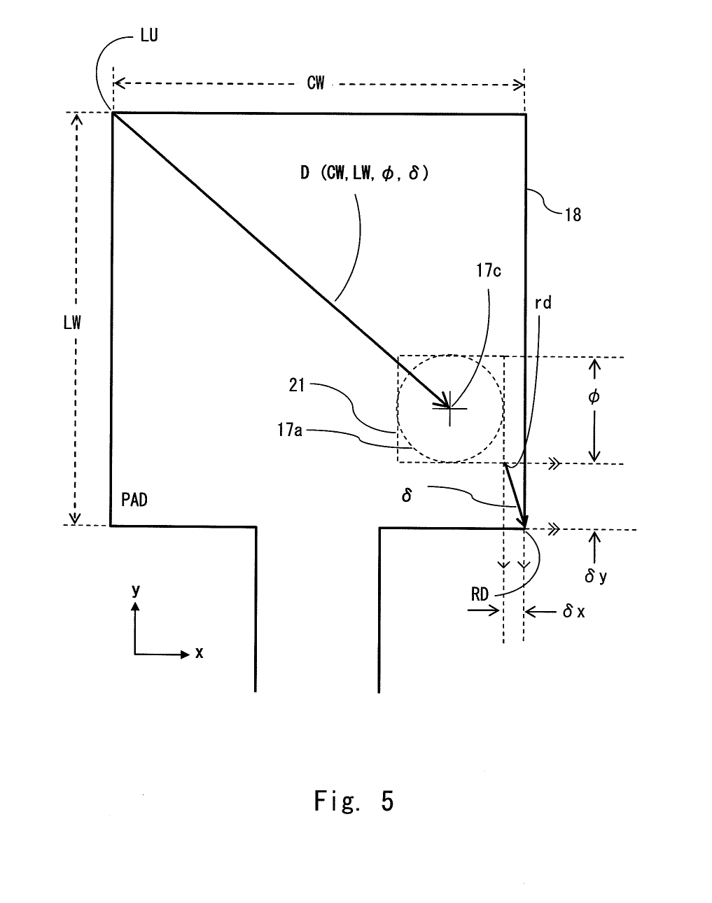

FIG. 4 is a flow chart showing further detail of the operation of teaching, which is the operation of step S3 in FIG. 3. First, the product information, the probe card information, and the prober information stored in the storage 11 are read into the controller 12 (step S11). Next, the diagonal vector D of the pad (CW, LW, φ, δ) is calculated (step S12). Note that CW denotes the size of the pad in the x direction (crosswidth), LW denotes the size of the pad in the y direction (lengthwidth), and φ denotes the diameter of the tip of the probe needle. The vector value δ is a margin vector.

The diagonal vector D will be described. FIG. 5 shows an outline of the test pad 18 and the diagonal vector D. A method of calculating the diagonal vector D is as shown below. A circle 17a shown by a dashed line shows a connection part of the test pad 18 and the tip part of the probe needle tip 17. Further, the central point of the circle 17a is denoted by a central point 17c. The size of the test pad 18 is indicated by a rectangle having lengths CW and LW in the directions of x and y axes, respectively.

First, a lozenge 21 circumscribed on the tip part of the probe needle 17 is considered. Each of two sides that share a lower right corner RD of the lozenge 21 is parallel to the side of the pad that is adjacent. As a matter of course, when the angle of the pad is at right angles, the lozenge is a rectangle. When the shape of the needle tip can be approached to a circle, the lozenge is a square. In FIG. 5, the lozenge is substantially a square, as an example.

Next, a margin vector δ is calculated. The margin vector δ indicates deviation amount of the needle tip when the probe needle 17 is pressed to the test pad 18 for conduction. The margin vector δ can be obtained from the prober information, the probe card information, and information of pressure (overdrive) from when the probe needle contacts the pad to be electrically connected. Further, since the margin vector δ typically depends on the inclination of the probe card needle 17 with respect to x and y axes, it varies for each probe needle 17 corresponding to the pad.

The margin vector δ is a value that is experimentally determined including the positional accuracy error of the prober obtained from the prober information. As a matter of course, the margin vector may be 0 when high accuracy is not required.

Each map of the pad of the vector δ to each side is denoted by δx and δy. These values are used in the flow chart to check corners described below. In FIG. 5, the margin vector δ is enlarged for the sake of convenience of explanation. In practice, however, the margin vector δ is substantially smaller than the tip diameter of the probe needle. Other drawings show δ of a typical size.

A method of calculating the vector D will be described. The position of the lozenge 21 is calculated so that a point obtained by moving a lower right corner rd of the lozenge 21 circumscribed on the contact part 17a of the probe needle 17 by the margin vector δ becomes the pad lower right corner RD. Then, a vector from an upper left corner LU of the pad to the central point of the probe needle tip 17 inscribed on the lozenge 21 is denoted by the diagonal vector D.

When the center of the probe needle tip is in the upper left corner of the pad, the position of the probe is moved by D. When the center of the probe needle tip further moves in the +x direction by φ+δx or in the −y direction by φ+δy, it moves to a boundary of conduction and non-conduction.

When the tip of the probe needle 17 is positioned in the edge of the pad, if the probe needle 17 moves outside the pad by the diameter φ of the needle tip, the reproducibility of the boundary between the conduction and non-conduction degrades by the deviation amount of the needle tip at the time of probing. In the first embodiment, the margin vector is obtained, which makes it possible to judge the conduction or non-conduction with higher reproducibility.

Referring back to FIG. 4, the teaching program will further be described in detail. Upon calculation of the diagonal vector D, the angles (θ) of the IC chip 14 and the probe card are adjusted (step S13). Typically, the probe card attached to the station head by hand is more or less deviated from the X-Y axes of the semiconductor inspection device 1. The difference in angles is denoted by θ, which should be approached to 0 by θ adjustment processing. The orthogonal coordinates of the semiconductor device after performing θ adjustment is set as x-y coordinates of the semiconductor inspection device 1.

Next, the pad upper left coordinates (PLU) are obtained (step S14). As will be described below, when the pad upper left coordinates are successfully obtained, FlagS is On. It is checked, by observing the FlagS, whether the pad upper left coordinates are successfully obtained (step S15). If not (step S15: No), the teaching is stopped, and an alarm is activated to notify the operator of the failure (step S16).

When FlagS is On (step S16: Yes), the station head 10 is moved by the diagonal vector D (step S17). According to the definition of the diagonal vector D, the probe needle 17 moves to a position at which the needle tip contacts with the pad near a diagonally opposite corner (lower right corner) of the pad of the IC chip 14.

When the pad upper left coordinates are successfully obtained and the conduction check after movement by the diagonal vector D is successfully performed, it may be said that the coordinates of the pad can be obtained with sufficient accuracy compared with the conventional alignment by hand. In this case, as will be described below, the value after the movement by the diagonal vector D which is the information of the shape of the pad can be considered as pad lower right coordinates (PRD). Then the process moves to step S21, where pad center coordinates (PC) may be calculated. The following description shows a case in which step S18 and the following steps are actually executed, assuming a case in which further accuracy is required or validity of the information of the shape of the pad is checked.

Next, the pad lower right coordinates (PRD) are obtained (step S18). As will be described below, when the pad lower right coordinates are successfully obtained, FlagS is On. It is checked, by observing the FlagS, whether the pad lower right coordinates are successfully obtained (step S19). If not (step S19: No), the teaching is stopped, and an alarm is activated to notify the operator of the failure (step S20).

When FlagS is On (step S19: Yes), the center coordinates of the pad are calculated (step S21).

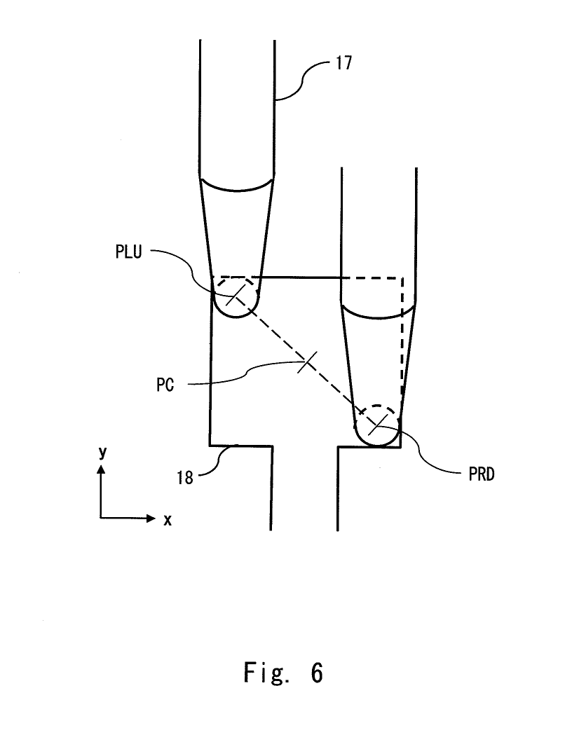

FIG. 6 shows a concept for obtaining the middle point between the lower right coordinates (PRD) and the upper left corner (PLU) of the pad of the IC chip on the layout. After the pad lower right coordinates are obtained, the pad center (PC) coordinates are obtained according to the following formula.

PC=(PLU+PRD)/2

As stated above, the central coordinates of the test pad 18 can be obtained by obtaining the middle point between the upper left apex coordinates and the lower right apex coordinates of the test pad 18.

The initial set values of the coordinates of the probe card 16 are calculated from the pad center coordinate values, and the calculated initial set values are stored in the storage 11.

FIG. 7 shows a state in which the position of the probe card 16 is adjusted with respect to the test pad 18 for connection.

The initial set values may be electromagnetically stored in the storage 11. When the semiconductor inspection device 1 performs inspection of a tape package (TAB (Tape Automated Bonding), COF (Chip on Firm) or the like), the IC chip 14 is replaced by another IC chip 14 as a result of the movement of the tape, without moving the station head 10. In such a case, the initial set values are mechanically stored as the probe card position. The semiconductor inspection device 1 according to the first embodiment not only includes the one that stores the initial set values in the storage 11 as electrical signals but also includes the one that mechanically stores the relative position of the probe card in the station head 10.

Described above is the outline of the teaching of the prober. Next, the processing of detecting the apex of the test pad 18 will be described.

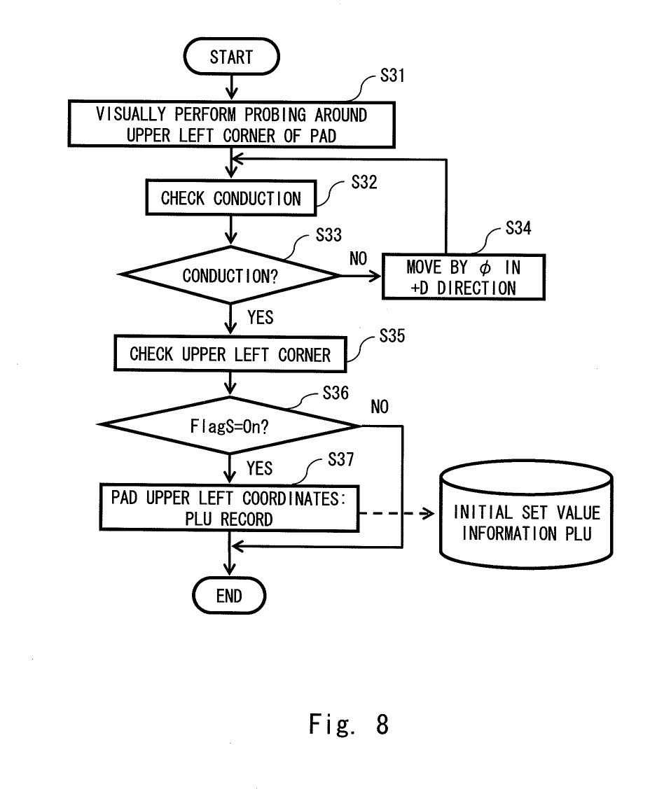

FIG. 8 is a flow chart showing a method of obtaining pad upper left coordinates (hereinafter referred to as PLU) which is a part of the teaching S3 of the semiconductor inspection device 1. First, an operator visually contacts the probe needle 17 around the upper left corner of the test pad 18 for probing (step S31).

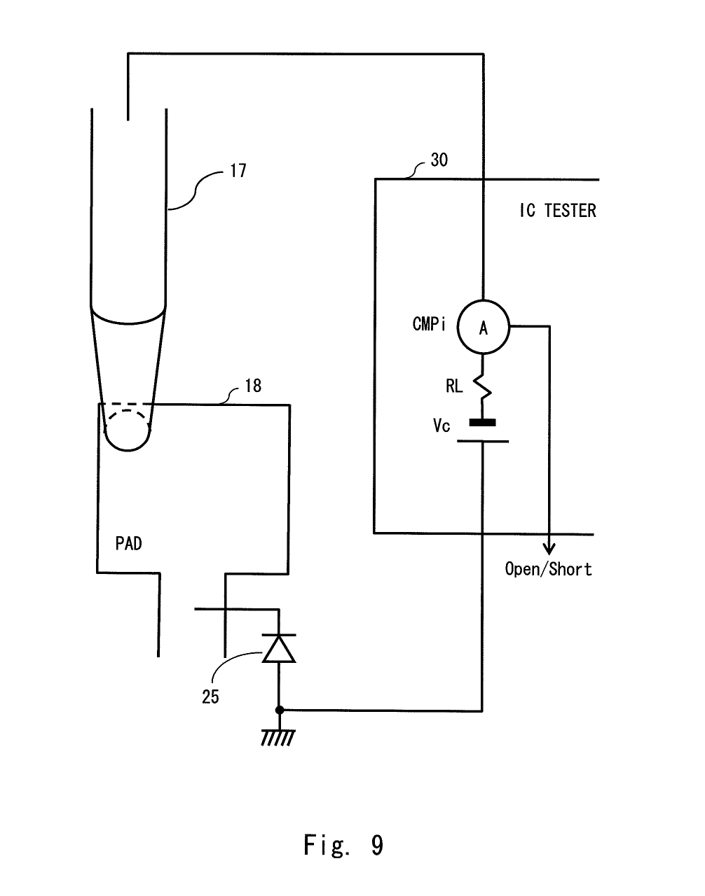

The probing will be described. FIG. 9 shows an example of the conduction check method. Typically, the pad of the IC chip 14 is connected to the GND through a diode 25 with reverse bias for ESD (Electrostatic Discharge) protection. The test pad 18 connected to the pad of the IC chip 14 is also connected to the GND through the ESD protection diode 25 with reverse bias as well. When the pad which is to be tested is a GND terminal, the pad of the IC chip 14 is directly connected to the GND.

An IC tester 30 includes a comparator CMPi, a resistor RL, and a constant voltage power supply Vc. The comparator CMPi is connected to the probe needle 17. The other end of the comparator CMPi is connected to the minus electrode of the constant voltage power supply Vc through the resistor RL. The plus electrode of the constant voltage power supply Vc is connected to the protection diode 25 and the GND.

The resistor RL adjusts the current value to the threshold of the current comparator CMPi. The resistor RL also serves as a current limiting resistor when the inspection target is a GND pad.

When the conduction state is checked, the IC tester 30 supplies a lower potential (Vc) than the ground of the IC tester 30 to the probe needle 17. When the probe needle 17 is connected to the test pad 18, a closed loop is formed, which allows a current to flow in the current comparator CMPi of the IC tester 30. It is determined whether the conduction state is kept (Short) or not (Open) by observing this value, and the inspection result regarding whether the conduction is made to the semiconductor inspection device 1 is output.

The voltage of the constant voltage source Vc is set to Vc≧VF when the inspection target is a pad other than the GND pad, and set below the forward voltage VF (Vc<VF) when the inspection target is the GND pad.

The voltage of the constant voltage source Vc is set to the voltage equal to or larger than the forward voltage VF of the diode 25, which is a value corresponding to the threshold (ThCMPi) of the comparator CMPi when the inspection target is a pad other than the GND pad. When the parasitic resistance of the measurement system including contact resistance between the pad and the probe needle is RP, this relation is expressed by the following formula (1).

Vc>ThCMPi·(RL+RP)+VF (1)

When the GND pad is the target, the value corresponding to the resistor RL and the threshold ThCMPi of the comparator CMPi is set. This relation is expressed by the following formula (2).

Vc>ThCMPi·(RL+RP) (2)

The method described above is used to check the conduction state between the probe needle and the pad of the IC.

Returning to FIG. 8, the method of obtaining the upper left coordinates PLU of the pad will be described further in detail. As shown in FIG. 9, the IC tester 30 is used to perform probing, thereby checking the conduction state (step S32). When the probe needle and the pad of the IC are not conducted (step S33: No), it means the probing location is outside the pad. In such a case, the probe needle is moved by the diameter φ of the probe needle tip in the direction of the vector D (step S34). The operations from step S12 are repeated until when the conduction state is checked. In practice, the conduction state should be achieved within several times of repeating. If the conduction state cannot be achieved even after the repeated operations, the operation is stopped once to seek another cause of the problem.

When the conduction state is detected (step S33: Yes), the upper left apex of the test pad 18 is detected in its probing position (step S35). When the detection is not successfully achieved (step S36: No), the processing is finished. When the detection is successfully achieved (step S36: Yes), the upper left apex coordinates of the test pad 18 are detected, which are stored in the storage 11 as initial set values (step S37).

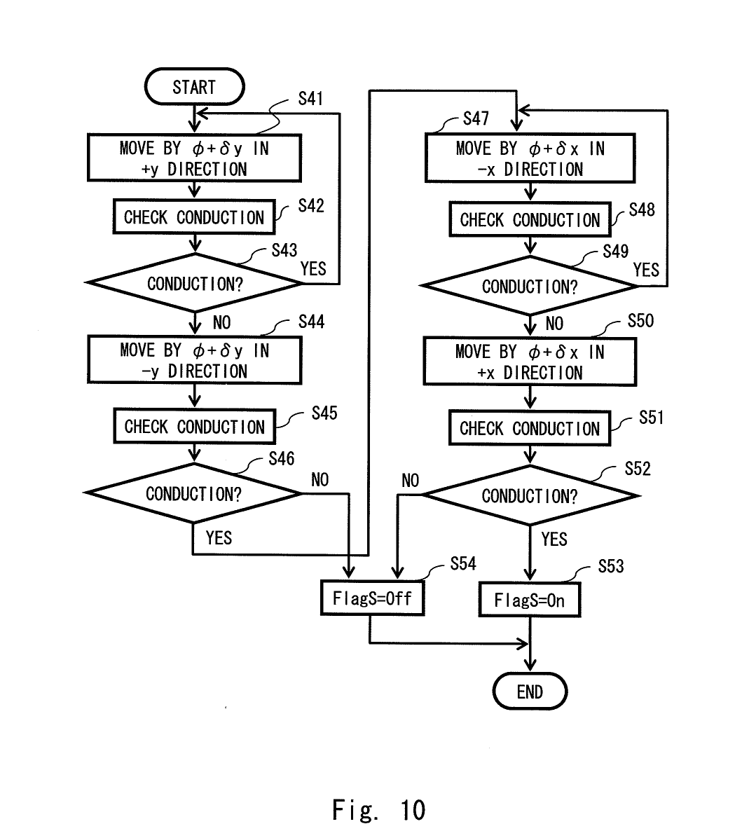

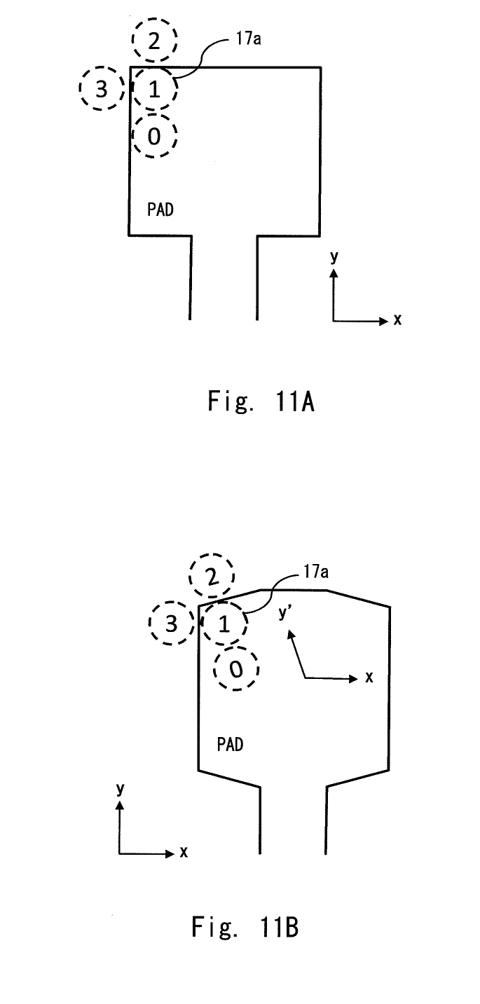

The processing for detecting the apex coordinates of the test pad 18 according to the first embodiment will further be described in detail. As one example, the upper left apex coordinates of the test pad 18 will be described. FIG. 10 is a flow chart describing step S35 shown in FIG. 8 further in detail, and shows a method of checking the upper left apex of the test pad 18. Further, FIGS. 11A and 11B each shows positions of the contact part 17a between the test pad 18 and the probe needle 17.

First, at step S33 shown in FIG. 8, the conduction state is checked at the initial position at which the probe needle 17 is visually set. When the conduction state is detected, the probe needle 17 is moved by φ+δy in the +y direction (step S41) for probing (step S42), to check non-conduction (step S43). When the conduction state is detected (step S43: Yes), the probe needle 17 is moved by φ+δy again in the +y direction (step S41) for probing (step S42), to check non-conduction (step S43).

The operations from step S41 to S43 will be described. When the needle tip of the probe needle 17 is initially in the position 1 shown in FIG. 11A, one movement in the +y direction makes the needle tip of the probe needle 17 move to the position 2, which makes the state non-conduction.

When the needle tip of the probe needle 17 is initially in the position 0, one movement in the +y direction makes the needle tip of the probe needle move to the position 1 for conduction. Accordingly, the needle tip needs to be moved to the position 2 by further movement in the +y direction.

By the operations from step S41 to step S43, the position of the edge of the pad in the +y direction is checked.

Next, when the non-conduction state is detected (step S43: No), the needle tip is returned by being moved by φ+δy in the −y direction (step S44), to check the conduction state again (step S45). When the conduction state is not detected (step S46: No), there is no reproducibility of the probing. In such a case, the success flag (FlagS) is set to failure (Off) for completion.

When the conduction state is detected (step S46: Yes), the needle tip is moved by φ+δx in the −x direction (step S47) for probing, to check the non-conduction state (step S48). When the conduction state is detected (step S49: Yes), the needle tip is moved by φ+δx again in the −x direction for probing (step S47), to check the non-conduction state (step S48). The operations from step S47 to step S49 are the same to the processing performed in the +y direction, except its direction.

When the non-conduction is detected as a result of movement of the probe needle 17 in the −x direction, this indicates that the position of the needle tip of the probe needle 17 shown in FIG. 11A is moved from the position 1 to the position 3, and the conduction and non-conduction are detected.

This means that the position of the edge of the pad in the left (−x) direction is checked. When the non-conduction is detected (step S49: No), the needle tip is moved by φ+δx in the +x direction (step S50), and the conduction state is checked again (step S51). When the conduction is not detected (step S52: No), it means there is no reproducibility of probing. In such a case, the success flag (FlagS) is set to failure (Off) to finish the processing (step S54).

When the conduction is detected (step S52: Yes), it means that the probe needle tip is in the position that satisfies the condition of PLU. In such a case, the success flag (FlagS) is set to success (On) (step S53), and stores the positional coordinates of this time as PLU to terminate the processing. This means that the positional coordinates PLU of the upper left corner are successfully obtained.

FIG. 11A shows a case in which the upper left corner is checked in the typical rectangular pad. Since the lead 20 on the tape 15 is typically made of copper, the test pad 18 is also made of copper. Typically, a copper wire can stand probing performed on the same position for three or more times. The processing for detecting the upper left apex this time would not cause any problem since PLU can be obtained by probing performed on the upper left corner (probe needle tip 1) of up to three times.

FIG. 11B shows a case in which processing for detecting the upper left apex is applied to a deformed pad having an upper side with varied angles with respect to x direction. In such a case, when it is recognized that the pad is not rectangle from the product information, y′ is defined in the direction perpendicular to the upper side. Then the needle tip is moved in ±y′ direction instead of ±y direction to check the corner of the pad. The coordinates eventually obtained are stored as the original x-y coordinate system, thereby capable of performing processing for detecting the upper left apex as is similar to the rectangular pad shown in FIG. 11A. In the similar way, the method can address with a variation in the x direction and variations in the x and y directions.

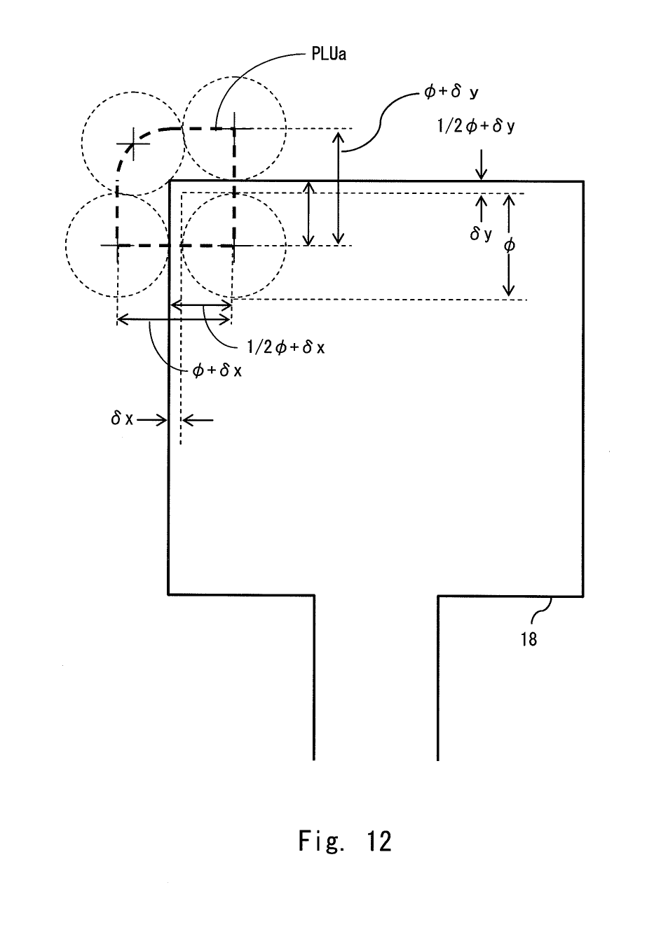

FIG. 12 shows an accuracy of the upper left coordinates PLU. The contact part 17a in FIG. 12 shows the range of the prober needle tip that satisfies the condition of PLU. Consider the range of the prober needle tip by the central position of the prober needle. The condition for checking the upper left apex can be satisfied to the position of (1/2φ+δx, 1/2φ+δy) at maximum inside the pad, and to the position of radius (φ/2) of φ at maximum outside the pad. The part surrounded by a thick dotted line in FIG. 12 (PLU range) is the range of the position of the center of the prober needle tip that satisfies the condition of the upper left apex detection processing. The positional accuracy is within the range of (φ+δx, φ+δy) at maximum. The positional accuracy can further be increased by also checking processing for detecting the lower right coordinates (PRD acquisition).

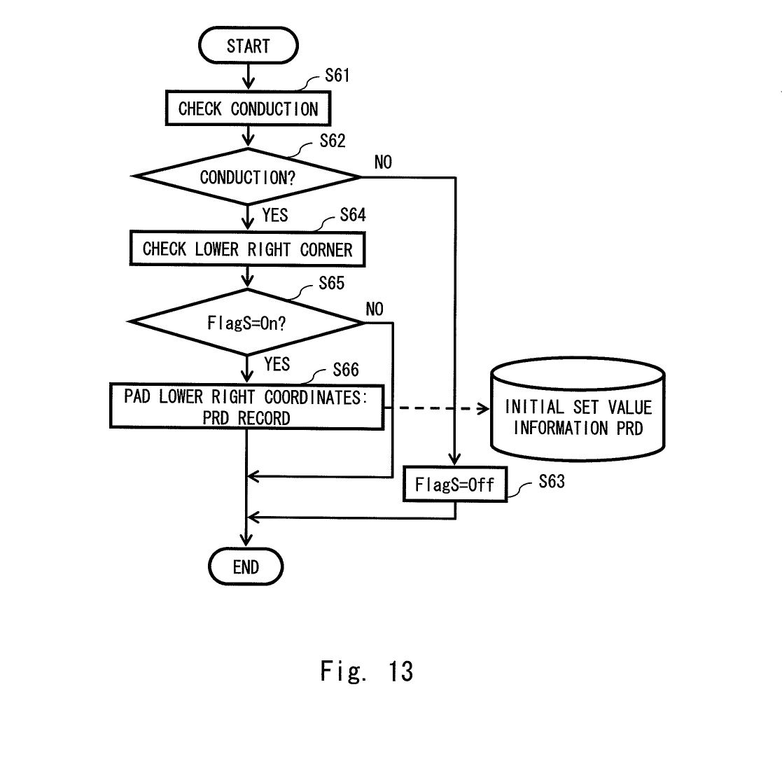

Next, a method of obtaining the lower right coordinates (PRD) of the test pad 18 will be described. FIG. 13 is a flow chart showing a method of obtaining pad lower right coordinates (PRD). After the upper left coordinates PLU are obtained in step S14 in FIG. 4, the needle tip is moved by the diagonal vector D from the position of PLU in step S17. From the definition of the diagonal vector D, if there is no error in the data and the control of the prober of the semiconductor inspection device 1, the probe needle should be provided on the pad.

First, in the coordinates after movement, the conduction is checked (step S61). When the conduction is not detected (step S61: No), this means that there is an error in the data or the control of the prober. In such a case, the success flag (FlagS) is set to failure (Off) (step S63), to terminate the processing.

When the conduction is detected (step S62: Yes), the lower right corner is checked in its position of probing (step S64). The lower right corner is checked in order to improve the positional accuracy of the lower right coordinates PRD and the upper left coordinates PLU that are obtained. Accordingly, the process of checking the lower right corner can be omitted when reduction of set time is prioritized over an increase in the positional accuracy. The maximum positional accuracy when the process is omitted is (φ+δx, φ+δy) as described with reference to FIG. 12.

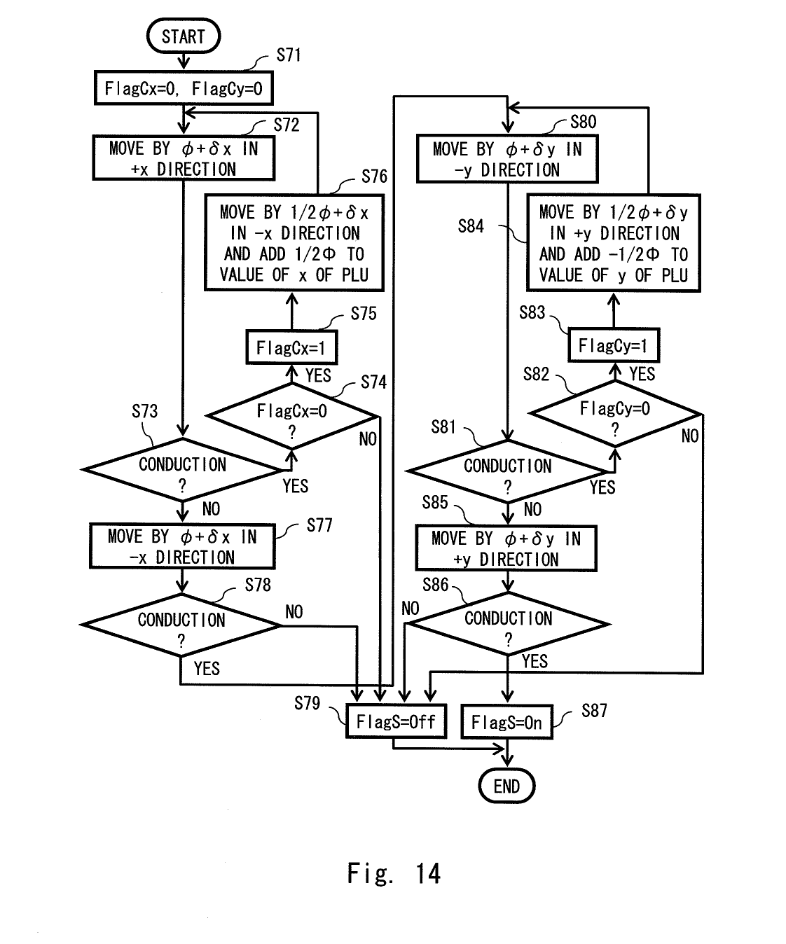

The processing for detecting the lower right apex of the test pad 18 will be described. FIG. 14 is a flow chart showing the method of processing for detecting the lower right apex.

First, each of the positional accuracy improvement flags (FlagCx, FlagCy) is set to 0 (step S71). Next, the needle tip is moved by φ+δx in the +x direction (step S72), to check conduction (step S73). Although the step of [conduction check] is omitted in FIG. 14, this step is performed before the condition judgment <conduction?>, as described above. The same can be applied also to the description below.

When the conduction is detected in the coordinates after the movement (step S73: Yes), from the definition of the diagonal vector D, the central coordinates PLU of the probe needle in the upper left that are already obtained are outside the pad. In this case, it is checked whether FlagCx is 0 (first improvement of positional accuracy in the x direction) (step S74). When FlagCx is not 0, it is not the first check of the positional accuracy in the x direction (step S74: No). However, there is no possibility that this improvement of the positional accuracy is the second time or more. Thus, if it is not the first check, the success flag (FlagS) is set to failure (Off), to terminate the process.

When it is the first improvement of positional accuracy (step S74: Yes), the positional accuracy improvement flag (FlagCx) is set to 1 (step S75), to improve the positional accuracy.

The probe position is moved by 1/2φ+δx in the x direction, and 1/2φ is added to the value of x of PLU that is already obtained, so as to set the value of x of PLU again (step S76). Therefore, the coordinate value is corrected to inside the pad even when the PLU is outside the pad in the −x direction. In this case, the positional accuracy of the PLU in the x direction is within the range of 1/2φ+δx, which means the positional accuracy can be improved without increasing the number of measurement points on the pad. Next, the probe tip is moved again by φ+δx in the +x direction (step 72), to check the conduction again (step S73).

When the non-condition is detected, the probe tip is moved by φ+δx in the −x direction to check the conduction. When the conduction is not detected, this means there is no reproducibility. Thus, the success flag (FlagS) is set to failure (Off) to complete the process.

When the conduction is detected (step S78: Yes), the positional accuracy is improved in the y direction in the similar way. The flow in the right side of FIG. 14 (step S80 to step S86) is similar to the flow in the left side described above except that +x is replaced by −y; and thus description will be omitted.

When the conduction is detected in step S86, the success flag (FlagS) is set to success (On) (step S87), to end the check of the lower right coordinates.

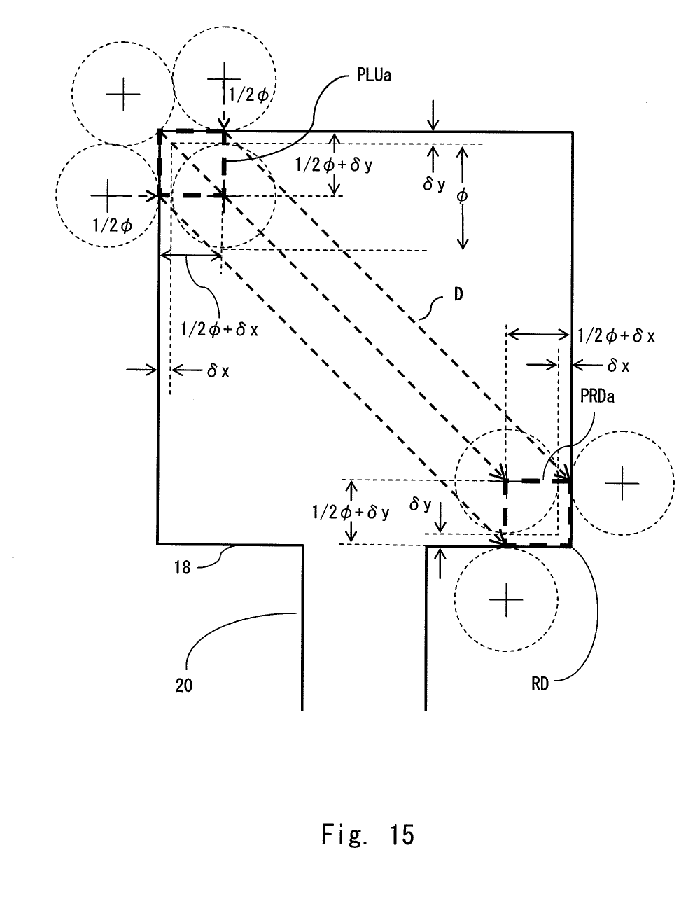

FIG. 15 shows a state in which the accuracy of the upper left coordinates PLU increases without increasing the number of measurement points on the pad when the lower right coordinates PRD are obtained. The range PLUa surrounded by a dotted line is a range of the upper left coordinates PLU when the upper left coordinates PLU are normally obtained. When the upper left coordinates PLU are within the range PLUa, if the needle tip is moved by the diagonal vector D, the central coordinates of the needle tip of the probe needle 17 are within the range of PRDa. Now, the upper left corner of the range PRDa is the point farthest from the corner RD that satisfies the condition of the lower right coordinates PRD. Accordingly, when the needle tip remains on the pad by one movement by φ+δx or φ+δy, this means that the upper left coordinates PLU exist outside the range PLUa. Accordingly, when the needle tip remains on the pad by one movement by φ+δx or φ+δy, the positional accuracy in the side that is outside the range PLUa is definitely improved. Accordingly, the values of the upper left coordinates PLU are within the range PLUa. At the same time, the start position of the check of the lower right is corrected in the similar way (φ+δx−(1/2φ+δx)=+1/2φ; similar for y direction as well), which results in the value of the lower right coordinates PRD within the range PRDa as well.

The x direction is checked before the y direction in the processing for detecting the lower right apex according to the first embodiment since it is assumed that the lead 20 of the test pad 18 is in the −y direction. Lead-out lines are not often covered with insulating films in land-type test pads. In order to prevent the probe needle from contacting the lead-out line which results in false decision, the check needs to be started from the x side that does not include a lead-out line.

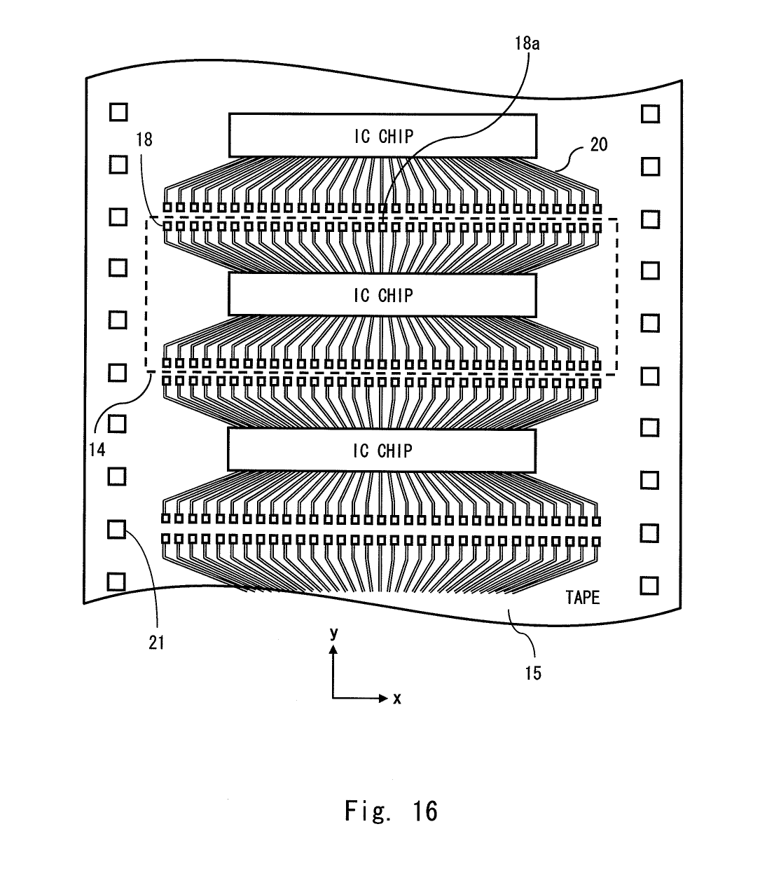

FIG. 16 shows positions of the IC chip 14 and the test pad 18 on which the teaching is executed on the layout according to the first embodiment. In the first embodiment, the processing for detecting a pad is performed after performing θ adjustment. However, it can be possible, in practice, that there is a slight deviation of θ between the probe card 16 and the IC chip 14. Further, since the probe card 16 is a machine product, the positional error may be generated in the probe card 16 for each probe needle. Therefore, it is desirable to execute the teaching on a pad 18a which is located about the center of the chip in order to minimize the accumulated error for all the test pads 18 of the IC chip 14. Typically, the probe needle 17 is mechanically contacted to the test pad 18, thereafter pressure is applied to achieve electrical contact in all the probe needles 17. At this time, the needle tip moves over the test pad 18. The center of the chip is expected to be the area in which the movement amount of the needle tip is the smallest. This is another reason that the teaching is performed on the pad 18a which is located about the center of the chip.

The semiconductor inspection device and the semiconductor inspection method of the first embodiment obtain coordinates of the position which is the corner of the pad of the IC in two diagonally opposite points. This position makes it possible to easily check the switching points of conduction and non-conduction with respect to x and y directions. Then, the central position of the pad is calculated from the coordinates of two diagonally opposite points, which makes it possible to obtain the central coordinates of the pad in shorter time and with high accuracy.

Further, according to the semiconductor inspection method of the present invention, there is no need to apply the probe needle around the center of the pad at the time of teaching. This can prevent the center of the pad from being scratched. Furthermore, even when the teaching is performed on an actual product, the quality of the product that is subjected to the teaching processing can be judged by a normal test. Thus, the low cost inspection can be executed without wasting chips.

### Second Embodiment

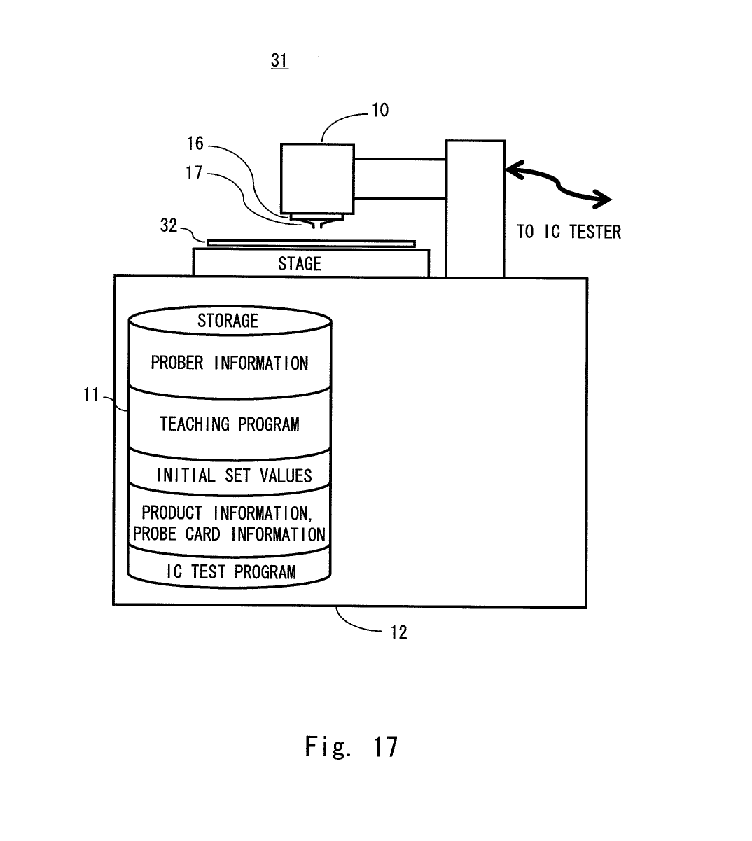

A semiconductor integrated circuit inspection device 31 according to a second embodiment will be described. FIG. 17 shows the semiconductor inspection device 31 according to the second embodiment. The semiconductor inspection device 31 according to the second embodiment is different from the semiconductor inspection device of the first embodiment in that an IC chip which is to be inspected is formed on a wafer, not on a tape package (TAB, COF or the like), and a test pad is of through hole type.

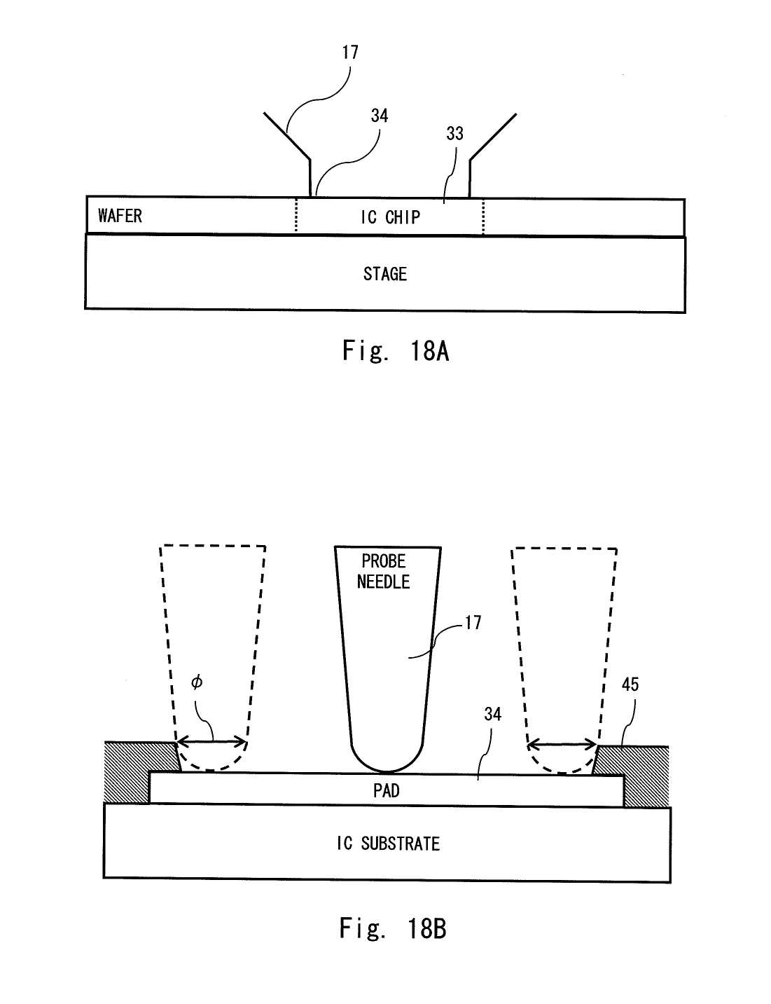

The semiconductor inspection device 31 includes a station head 10, a stage 13, a storage 11, and a controller 12. The station head fixes a probe card 16 including a probe needle 17 corresponding to a test pad 34 (see FIG. 23) of an IC chip 33 (see FIGS. 18A and 18B) which is the inspection target mounted in matrix on one element forming surface (IC mounted surface) of a main surface of a semiconductor wafer 32. The station head 10 moves back and forth and from side to side in parallel to the IC mounted surface of the semiconductor wafer 32. The stage 13 fixes the semiconductor wafer 32 by vacuum suction or the like, rotates with the semiconductor wafer 32 to perform θ adjustment. The storage 11 loads prober information which is data specific to a prober, product information of the IC chip 33 which is to be inspected, and probe card information corresponding to the IC chip 33, stores a teaching program and initial set values which are results of the teaching program, and stores an IC test program. The controller 12 controls the operations of the station head 10 and the stage 13.

FIGS. 18A and 18B each shows a test pad 34 according to the second embodiment. The test pad 34 according to the second embodiment is of through hole type, as shown in FIG. 18B. The test pad 34 is arranged in a bottom surface of a hole (through hole) on the surface of the IC chip 33.

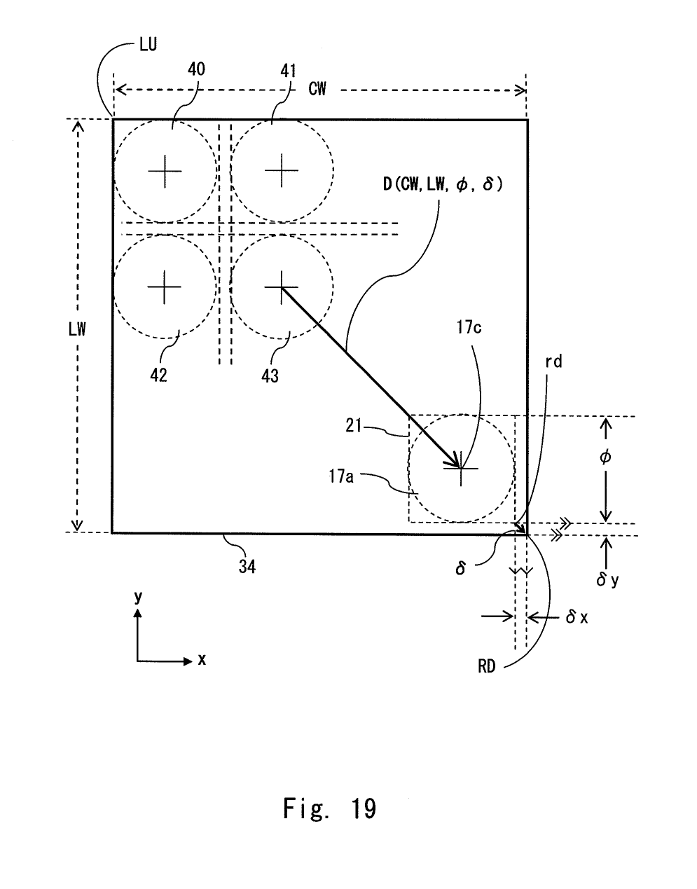

The product information of the IC chip 33 includes pad size information (CW, LW), pad shape information, IC chip size, and arrangement information of the IC chip 33 on the semiconductor wafer 32 that are required to calculate a diagonal vector D shown in FIG. 19. Typically, a pad through hole is opened in a cover film 45 and this opening is used as the pad of the IC chip 33. Thus, the actual size is not equal to the size of a pad electrode, but is equal to the size of the pad through hole. In the drawings according to the second embodiment, the pad is omitted and the pad through hole is used as the pad 41.

The probe card information includes size information of a diameter φ (see FIG. 18) of the probe needle tip required to calculate the diagonal vector D shown in FIG. 19, and physical information of the probe card required to calculate a margin vector δ.

The controller 12 includes the storage 11, and includes a circuit set mainly including a microcomputer. The controller 12 controls the station head, the stage, and a wafer loader (not shown) or the like that automatically mounts the semiconductor wafer on the stage according to the program and the data loaded from the storage. As a matter of course, the loading of the program and the data does not necessarily mean an actual data transfer, but also includes mere recognition of a pointer of various programs or data on the storage.

The controller 12 moves one or both of the station head 10 and the stage 13 up and down, thereby allowing the probe needle 17 to electrically connect to the pad of the IC chip 33, or to cancel the connection to the pad of the IC chip 33. Further, the station head 10 moves across the whole surface of the semiconductor wafer 32 by the control by the controller 12, and checks all the IC chips 33 in series.

Further, the station head 10 includes a wire that electrically connects the probe card 16 and an IC tester (not shown). This allows the station head 10 to transmit an output signal from the IC tester to the test pad 34 of the IC chip 33 through the probe card needle 17, and transmit an output signal from the test pad 34 of the IC chip 33 to the IC tester.

Further, the semiconductor inspection device 1 receives and processes a returned value from the IC tester as a result of executing the program of the prober. Further, the similar function can be achieved through the work by the operator who observes the result of the IC tester.

FIG. 19 shows a relation of the positions between contact parts 40 to 43 of the probe needle 17 and the test pad 34. With reference to FIG. 19, the start point when determining the diagonal vector D is considered. Circles 41 and 42 having the probe needle tip diameter are obtained by moving the contact part 40 inscribed on each side of the pad through hole forming a corner LU by δx in the x direction and by δy in the y direction, respectively. The start point is the center of a circle 43 having the common probe needle tip diameter obtained by moving the circles having the assumed needle tip diameter by δx and δy. The end point of the diagonal vector D is similar to that in the first embodiment.

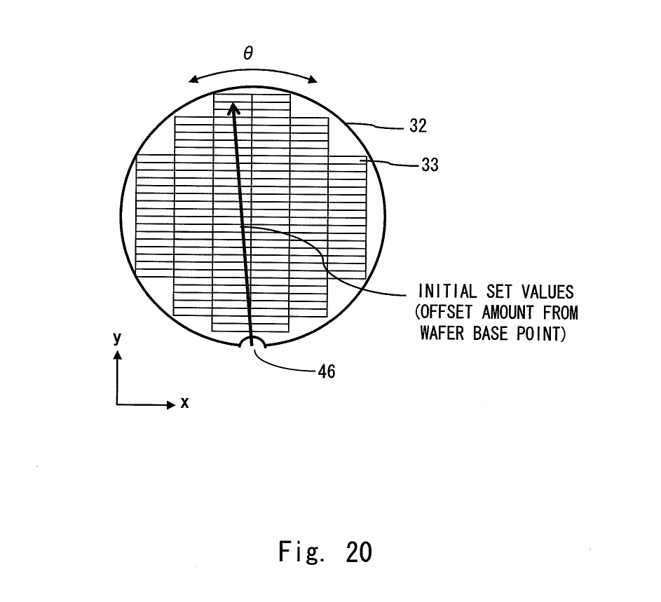

FIG. 20 shows the semiconductor wafer 32. As shown in FIG. 20, the initial set values are indicated by relative positional coordinates of a notch 46 which is the base point of the wafer from the center. The station head 10 is moved to the initial set values, thereby enabling the accurate test of the IC chip 33 that is tested first.

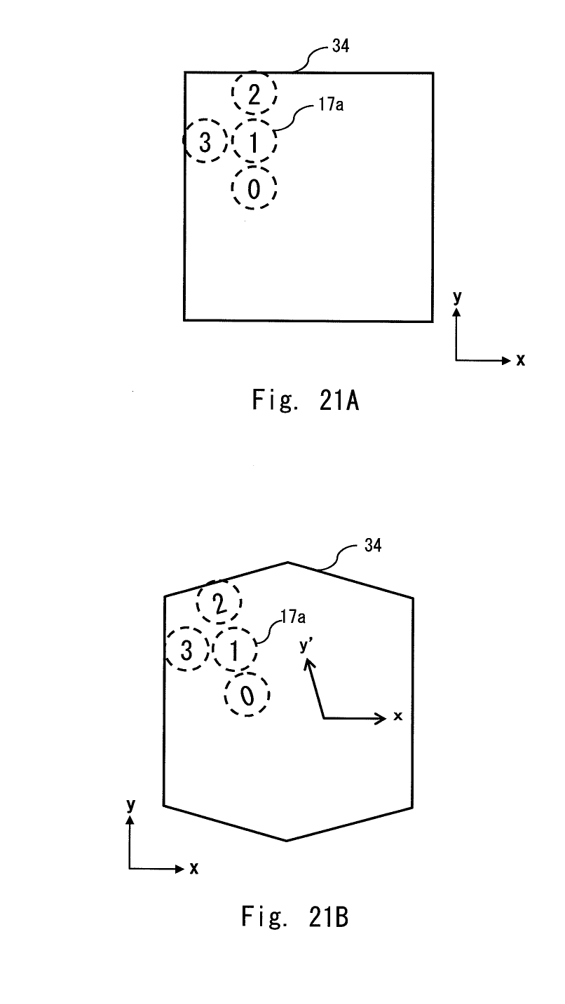

FIGS. 21A and 21B each shows positions of the needle tip of the probe needle 17 and the test pad 34. FIG. 21A shows a case in which a rectangular test pad is used, and FIG. 21B shows a case in which a deformed pad is used. As shown in FIG. 21A, when the processing for detecting the upper left apex of the test pad 34 is performed, all the probe needle tips are inside the test pad (pad through hole). The same thing can be applied to the deformed pad shown in FIG. 21B. Other operations including the description of y′ of the deformed pad are similar to those shown in FIG. 11 of the first embodiment.

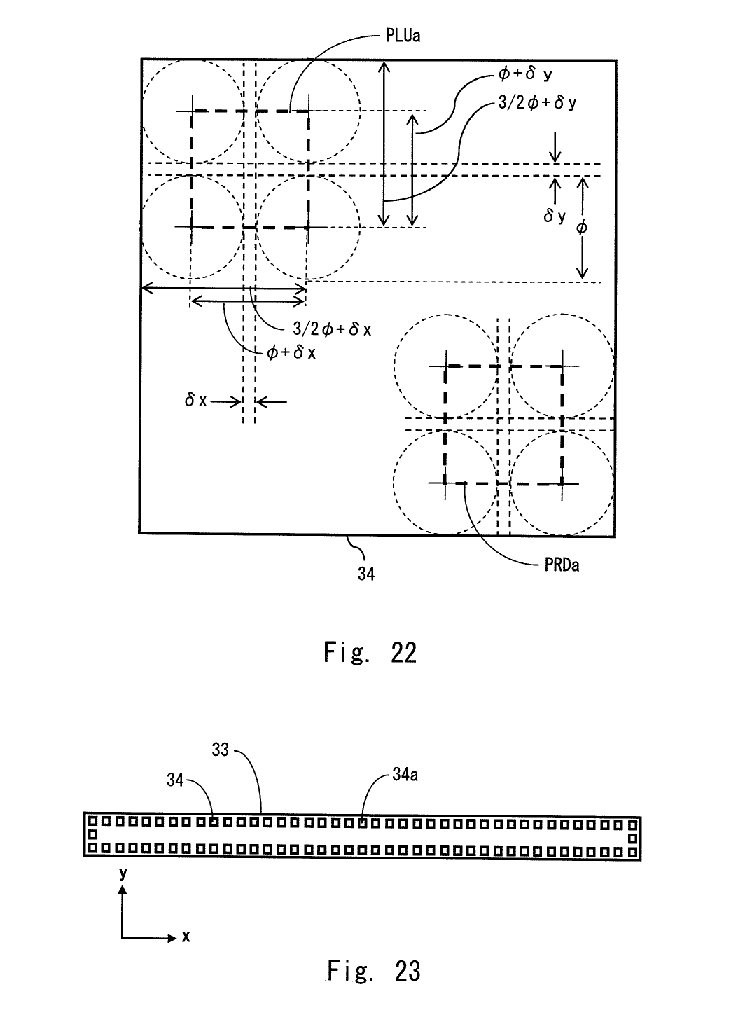

FIG. 22 shows expectation values of the accuracy of the pad center coordinates (PC). The accuracy of pad upper left coordinates (PLU) is within the range of PLU shown by the thick dotted line, and the accuracy of pad lower right coordinates (PRD) is within the range of PRD shown by the thick dotted line. Each of the coordinates has an interval of a vector D. The second embodiment is different from the first embodiment in that it is impossible to improve the positional accuracy of the pad by calculating pad lower right coordinates (PRD). Accordingly, the positional accuracy (x, y) of the pad center coordinates PC is (±(φ+δx)/2, ±(φ+δy)/2).

FIG. 23 shows the test pads 34 of the IC chip 33. As shown in FIG. 23, a teaching execution pad 34a is preferably the test pad around the center of the IC chip, as is the same to the first embodiment. Other operations are similar to those in the first embodiment.

Accordingly, the semiconductor inspection device according to the second embodiment can be applied to a semiconductor device having a pad of through hole type as well.

### Third Embodiment

A third embodiment will now be described. The third embodiment is different from the above embodiments in that it applies a method of calculating pad center coordinates according to another exemplary embodiment to improve the accuracy of θ adjustment at the same time as the detection of the position of the test pad.

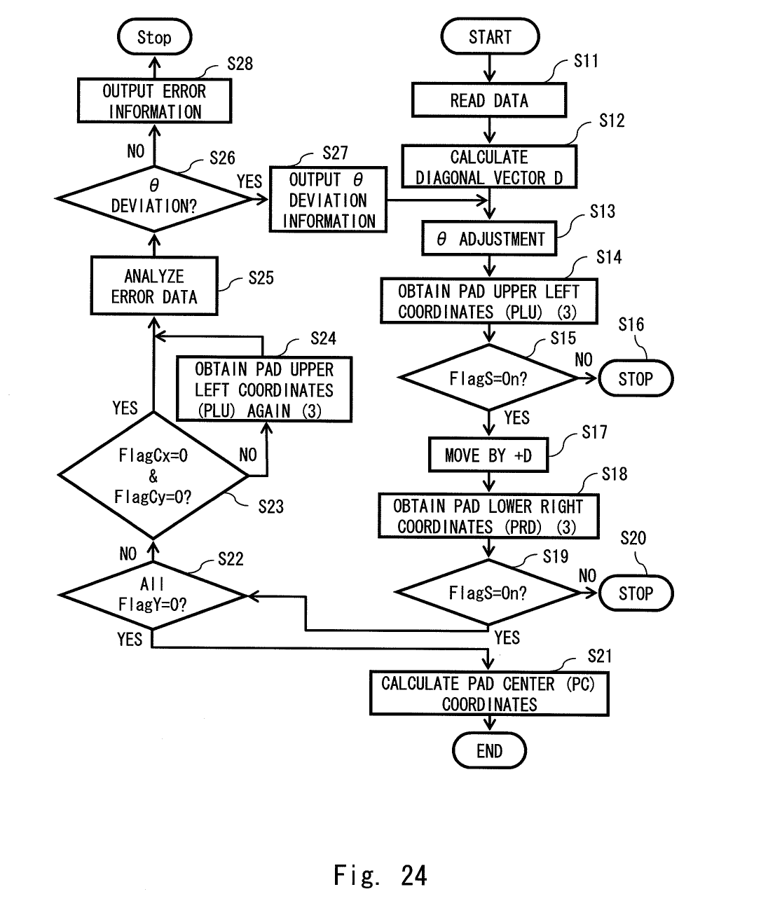

FIG. 24 is a flow chart showing a teaching method of a prober according to the third embodiment. The right side of the flow chart is similar to the above exemplary embodiments regarding a teaching execution pad 34a. In the following description, the difference between the third embodiment and the above exemplary embodiments will be described.

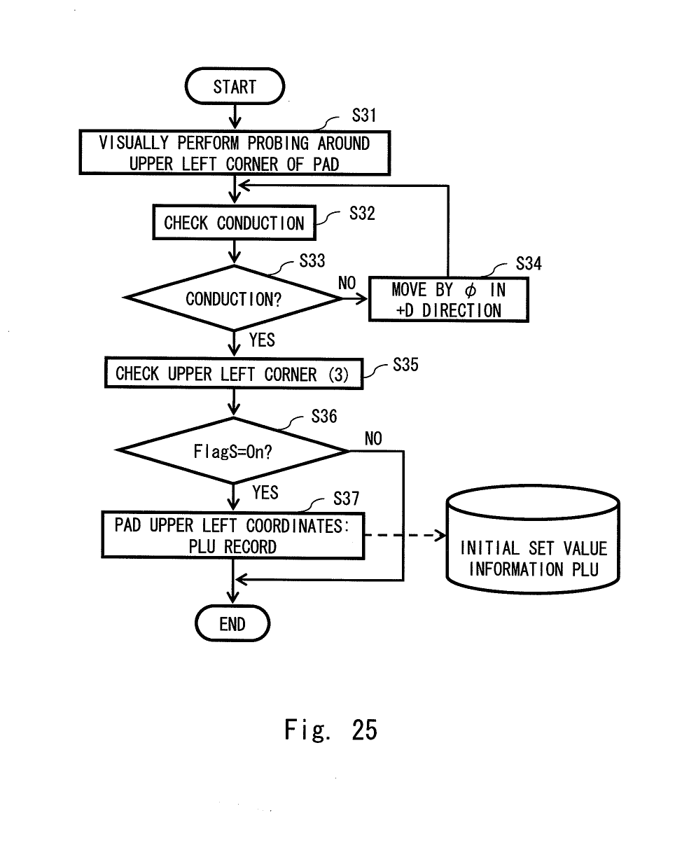

FIG. 25 is a flow chart showing a method of obtaining pad upper left coordinates (PLU) according to the third embodiment. The third embodiment is different from the above embodiments in the contents of upper left corner check (3). The processing of the teaching execution pad 34a is totally the same to that of the above exemplary embodiments, and thus description will be omitted.

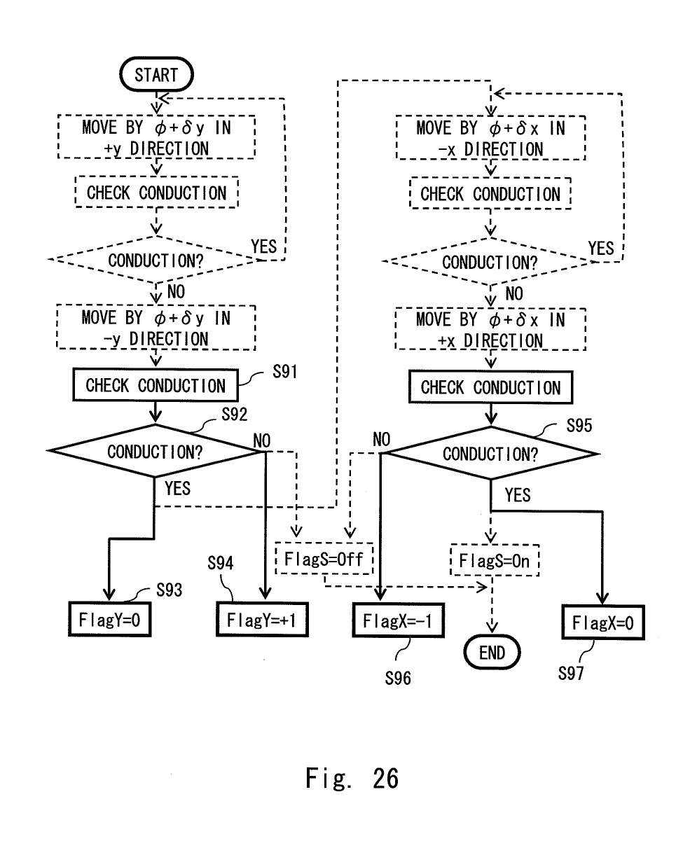

FIG. 26 is a flow chart showing processing for detecting an upper left apex according to the third embodiment. The flow indicated in dotted lines is the same to the processing for detecting the upper left apex shown in FIG. 10, and indicates the operation of processing of the teaching execution pad 34a. The flow indicated by solid lines is processing of the pads other than the teaching execution pad 34a. In the third embodiment, each test pad includes two flags (FlagX, FlagY) of four values (−1, 0, +1, +2).

Shown by the dotted lines in FIG. 26 is the flow of the teaching execution pad 34a according to the third embodiment. After the conduction is detected, the needle tip is moved by φ+δy in the +y direction to detect the non-conduction, followed by detection of the edge of the pad. Then, the needle tip is moved by φ+δy in the −y direction to come back to the original conduction check position. At this time, the conduction is checked for each of the pads other than the teaching execution pad 34a (step S91). When the conduction is detected (step S92: Yes), FlagY is set to 0 (step S93). When the conduction is not detected (step S92: No), FlagY is set to +1 (step S94). The value of FlagX is determined for the x direction in the similar way (steps S95 to S97).

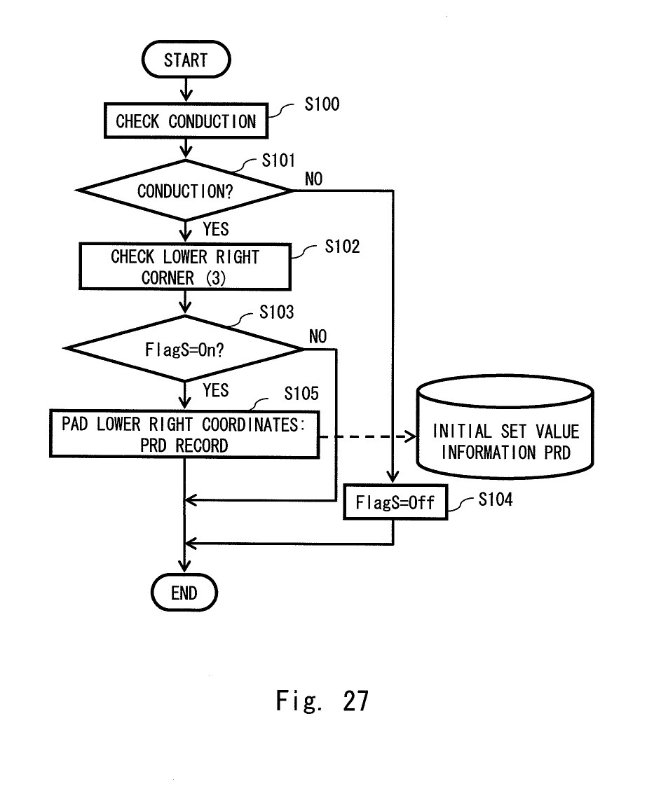

FIG. 27 is a flow chart showing a method of obtaining pad lower right coordinates (PRD) according to the third embodiment. The third embodiment is different from above exemplary embodiments in the contents of the processing for detecting a lower right apex (3). The processing of the teaching execution pad 34a is totally the same to that of the above embodiments; thus description will be omitted.

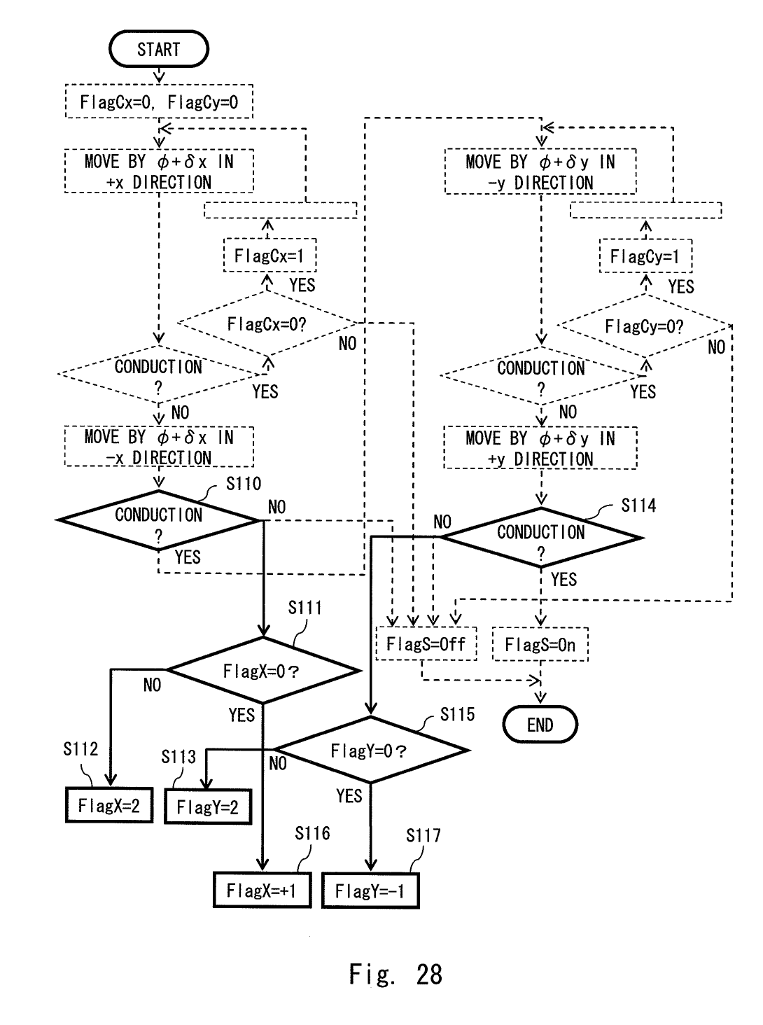

FIG. 28 shows a flow chart for detecting a lower right apex according to the third embodiment. The flow indicated by dotted lines is similar to the case of detecting the lower right apex shown in FIG. 14, and is processing of the teaching execution pad 34a. The flow indicated by solid lines is processing of the pads other than the teaching execution pad 34a.

According to the flow of the teaching execution pad 34a shown by the dotted lines, after the conduction is detected, the needle tip is moved by φ+δx in the +x direction to detect non-conduction (detect the edge of the pad). When the needle tip is moved by φ+δx in the −x direction to be back to the original conduction check position, the conduction state is checked in each of the pads other than the teaching execution pad 34a (step S110). When the conduction is detected (step S110: Yes), there is no change in FlagX. When the conduction is not detected, FlagX is set to +1 if the value of FlagX is 0 (step S111: Yes);

otherwise FlagX is set to 2 (step S111: No). The value of the FlagY is determined in the similar way for the y direction.

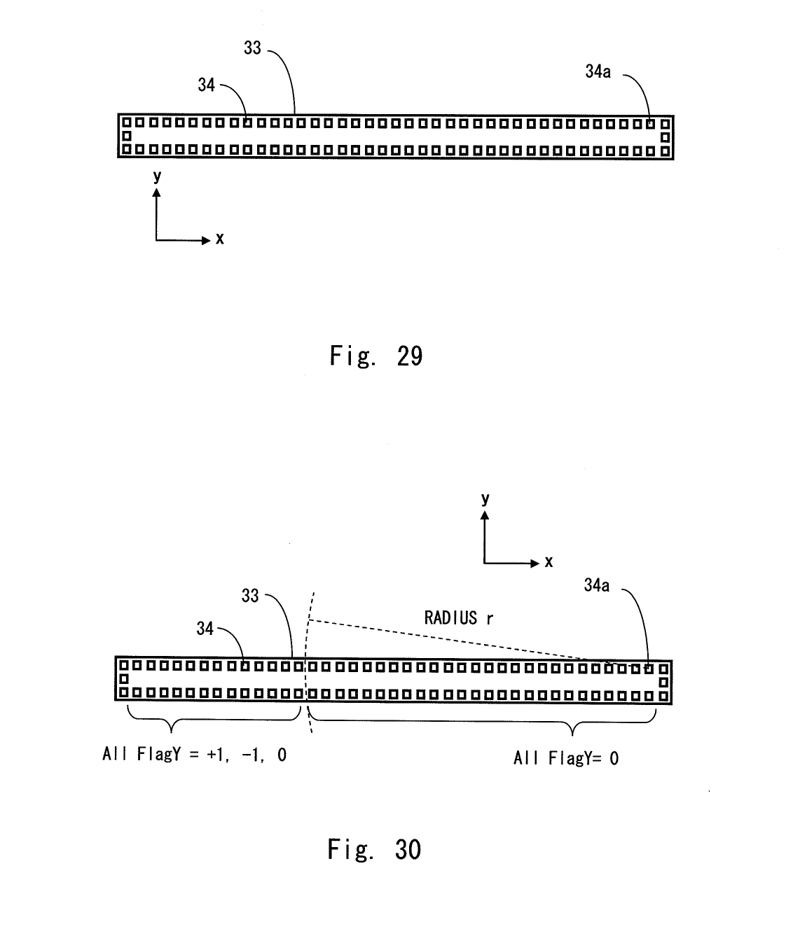

FIG. 29 shows an outline of a selection of the teaching execution pad 34a according to the third embodiment. In the first and second embodiments, the influence of θ deviation is reduced by selecting the test pad around the center of the semiconductor device. On the other hand, in the third embodiment, the test pad in the end part of the semiconductor integrated circuit is selected as the teaching execution pad 34a so as to induce the influence of the θ deviation.

Now, the flow in the left side of FIG. 24 will be described. When the flow to step S19 is completed and the result of step S19 is Yes, it is checked whether the values of all the FlagY other than the teaching execution pad 34a are 0 (step S22). If Yes in step S22, there is no θ deviation. Then the process goes to pad center (PC) coordinates calculation (step S21).

When not all the values of FlagY are 0 in step S22 (step S22: No), it is highly likely that the θ deviation is generated. Thus, it is checked whether both values of FlagCx and FlagCy are 0 (step S23). If No in step S23, the processing for improving the pad accuracy may be inaccurate. Then, the pad upper left coordinates (PLU) are obtained again (3), and the process goes to error data analysis (step S25).

When the result of step S23 is Yes, the process goes to error data analysis (step S25). When it is judged that there is no θ deviation as a result of error data analysis (step S25), it means abnormality of the probe card, the product data or the like. Then the process goes to error information output (step S28), to interrupt the processing.

When the result of the error data analysis (step S25) shows the θ deviation, the θ deviation amount obtained from the processing result of step S25 is output to the semiconductor inspection device 1 or 31. Upon receiving the θ deviation amount, the semiconductor inspection device performs correction for θ adjustment automatically or by hand, and the process repeats from step S13 again.

FIG. 30 shows a flow of the error data analysis (step S25) method shown in FIG. 24, and shows an error data analysis method regarding 0 deviation according to the third embodiment. The boundary between the part in which the values of FlagY of the successive test pads from the teaching execution pad 34a are 0 and the part in which the values of the FlagY are the same value of other than 0. When the boundary is detected, an arc that passes the boundary with the center of the teaching execution pad 34a is drawn, and its radius is denoted by r.

When the value of FlagY other than 0 is +1 or −1, the process goes back to FIG. 26, where the value of θ deviation is calculated according to the flow of step S22 <All FlagY=0?> and the following steps.

First, it is checked whether all the values of FlagY are 0 (step S22). When all the values of FlagY are 0 (step S22: Yes), no correction needs to be performed and the process moves to the processing for calculating the center coordinates of the pad (step S21). When not all the values of FlagY are 0 (step S22: No), it is checked whether FlagCx and FlagCy are 0 in order to check whether the correction is not performed before this processing (step S23). When FlagCx and FlagCy are not 0 (step S23: No), the processing for detecting the upper left apex of the test pad 18 is performed again (step S24), to analyze the error data (step S25). When both of FlagCx and FlagCy are 0 (step S23: Yes), the process directly goes to step S25, where the error data is analyzed.

When the result of the error data analysis shows the θ deviation (step S26: Yes), the information of θ deviation is fed back to the controller 12, to perform θ adjustment. When it is judged that there is no θ deviation (step S26: No), the error information is output to the controller 12 (step S26), to complete the processing.

Now, a method of calculating the θ deviation will be described. When the value of FlagY other than 0 is 1, the angle of the deviation Δθ can be calculated by formula (3).

(+πφ/2)/r [rad]≦Δθ≦+π(φ+δ)/r [rad] (3)

When the value of FlagY other than 0 is −1, the angle of θ deviation δθ can be calculated by the following formula.

−π(φ+δ)/r [rad]≦δθ≦(−πφ/2)/r [rad] (4)

The θ adjustment is performed automatically or by an operator based on the values obtained by formula (3) or (4), to repeat the flow of [θ adjustment] and the following processing in the right side of FIG. 26 again. The teaching execution pad 34a at this time is not the test pad in the end of the IC chip 31 of FIG. 29, but the test pad around the center of the semiconductor device shown in FIG. 18 or 25.

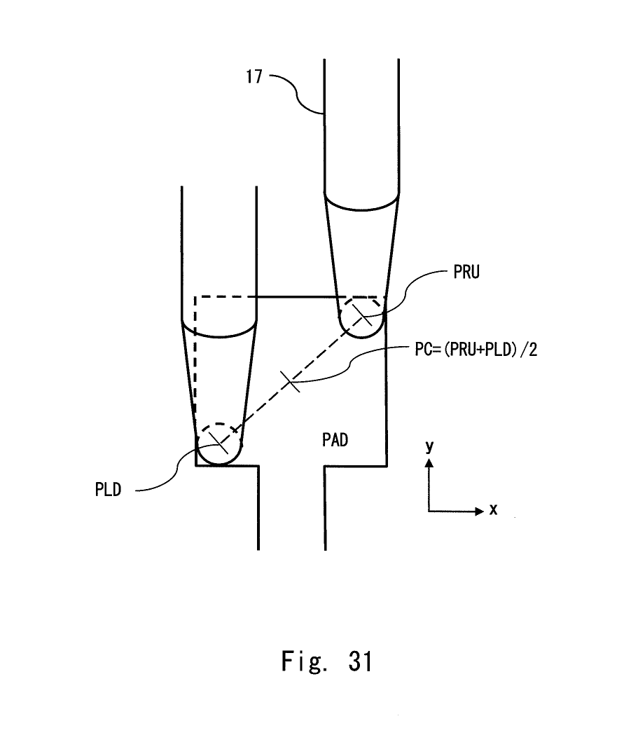

Further, in the third embodiment, the probing is performed on each pad up to three times or more. Thus, the test may not be correctly performed when the pad is made of sputtering aluminium and is damaged by probing. FIG. 31 shows positions of the probe needle 17 and the test pad. As shown in FIG. 31, the diagonal positions are set to upper right and lower left instead of upper left and lower right used in the above flow. This allows second acquisition of the pad center position information without giving a damage of probing to a central part of the test pad.

When the values of FlagY of all the pads are 0, the value of r is the distance to the pad having the value of FlagY which is the farthest from the teaching execution pad 34a. Then, the value of r can be obtained from the following formula (5).

(−πφ/r)/2 [rad]<Δθ<(+πφ/r)/2 [rad]

The accuracy of the θ adjustment cannot further be increased in the method according to the third embodiment. Thus, the pad size and the positional accuracy of the probe needle need to be set so as to allow this error.

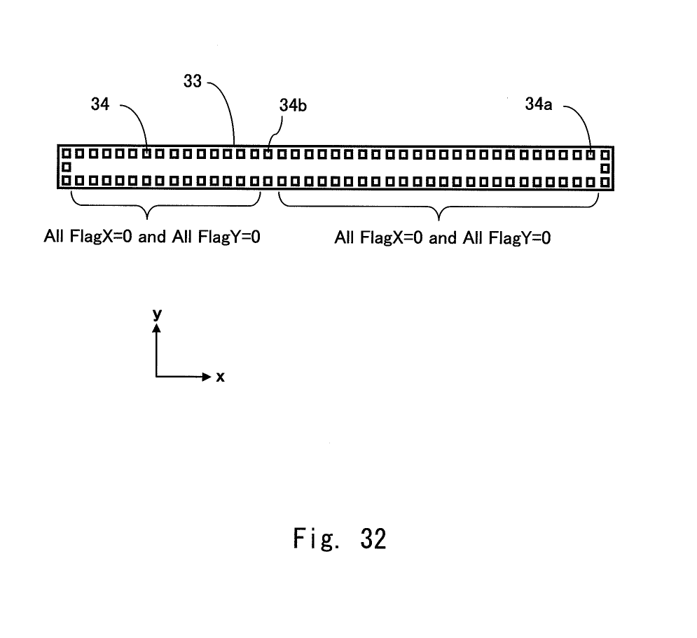

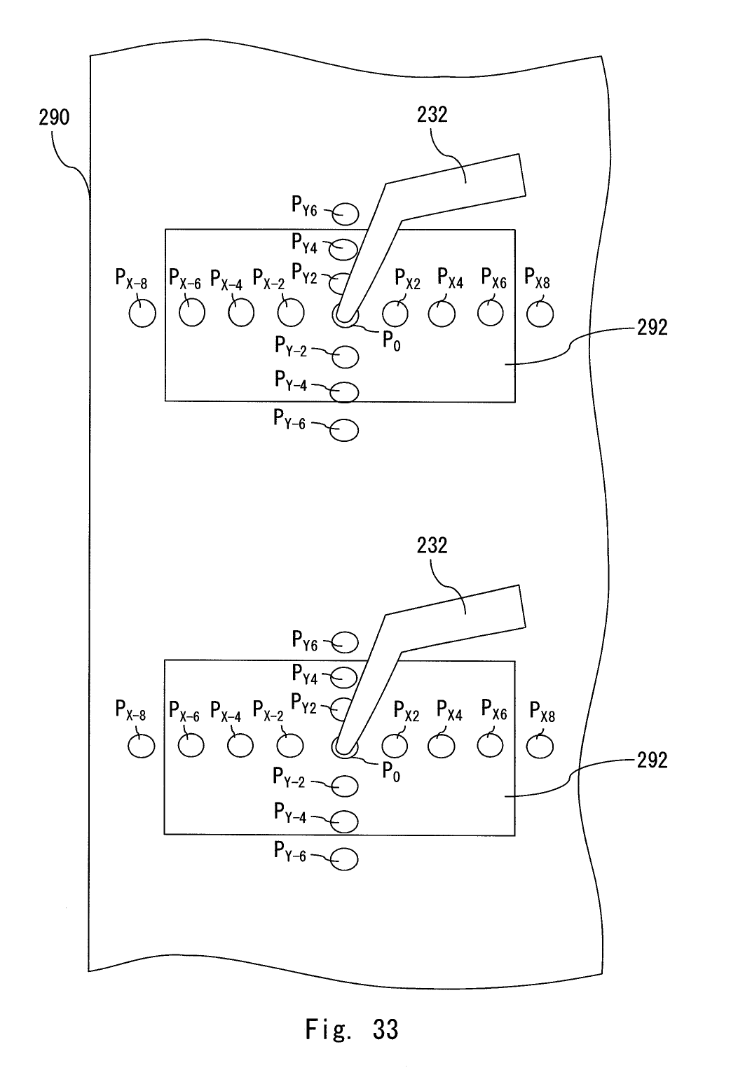

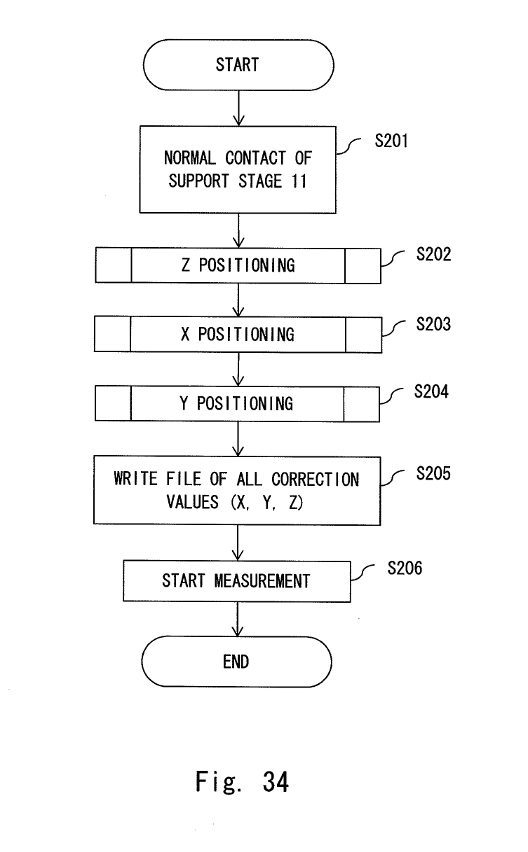

The flags of the pads other than the teaching execution pad 34a may have other values. In this case, if the combination of the IC chip and the probe card is correct, the positional accuracy of the probe needle may be decreased. FIG. 32 shows one example of the error data analysis in this case. In this example, description will be made of a case in which the flag of the pad 34b is other than 0, and the flags of the pads other than the pad 34b are 0. In this case, the trouble of the probe card may be estimated as shown below.
FlagX=0 and FlagY=+1 [symbol] the needle tip is deviated in the direction of +y
FlagX=0 and FlagY=−1 [symbol] the needle tip is deviated in the direction of −y
FlagX=+1 and FlagY=0 [symbol] the needle tip is deviated in the direction of +x
FlagX=−1 and FlagY=0 [symbol] the needle tip is deviated in the direction of −x
FlagX=2 or FlagY=2 [symbol] other troubles than stated above of the probe card or the pad

The θ adjustment accuracy increases when conduction is checked for all the pads other than the teaching execution pad 34a. However, in order to reduce costs, these pads may be divided into several groups, and only the representative pad of each group may be measured.

By applying the third embodiment to the first and second embodiments, the positional accuracy in the θ direction can be improved in addition to the positional accuracy of the probing in the X-Y direction.

According to the semiconductor inspection device of the third embodiment, the position of the prober can be calculated in a short time and with high accuracy.

The first, second, and third embodiments can be combined as desirable by one of ordinary skill in the art.

Note that the present invention is not limited to the embodiments described above, but can be changed as appropriate without departing from the spirit of the present invention. Further, each element shown in the drawings as a functional block executing various processing may include a CPU (Central Processing Unit), a memory, and other circuits in hardware, and may include a program loaded to a memory in software. It will be understood by a person skilled in the art that these functional blocks may be variously achieved only by hardware, software, or the combination thereof, and should not be limited to any one of them. The configuration of each device shown in the drawings is achieved by executing a program read into a storage device on a computer (PC (personal computer) or mobile terminal device), etc.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. An inspection device of a semiconductor integrated circuit comprising:
a drive unit that moves a probe card including a plurality of probe pins back and forth and from side to side, the respective probe pins corresponding to a plurality of pads connected to a plurality of terminals of a semiconductor;
a storage unit that stores arrangement of the semiconductor integrated circuit and a shape of the plurality of pads connected to the plurality of terminals of the semiconductor; and
a control unit that controls the drive unit based on the shape of the plurality of pads obtained from the storage unit, wherein
the control unit controls the drive unit, performs an apex detection processing pressing the probe pin to the semiconductor integrated circuit, detecting a position of the probe pin where conduction is detected and another position of the probe pin where conduction is not detected, and calculating coordinates of one apex of a inspection pad from detected positions, and calculates central coordinates of the inspection pad from information of the shape of the inspection pad based on the coordinates of the apex of the inspection pad, the inspection pad being a target to be inspected among the plurality of pads, and
the drive unit presses the probe pin to the calculated central coordinates of the inspection pad based on the control by the control unit to perform inspection.

2. The inspection device of the semiconductor integrated circuit according to claim 1, wherein
the control unit performs the apex detection processing on one apex of the inspection pad, performs the apex detection processing on an apex which is diagonally opposite to apex coordinates that are detected upon detection of one apex of the inspection pad, calculates a middle point of two apex coordinates upon detection of the diagonal apex to calculate central coordinates of the inspection pad.

3. The inspection device of the semiconductor integrated circuit according to claim 1, wherein
the storage unit stores a margin vector δ (δx, δy) and a diameter φ of the needle tip of the probe pin, the margin vector being a deviation amount of the needle tip of the probe pin when the probe pin is pressed to the inspection pad, and
the control unit performs detection processing based on the margin vector δ and a radius φ of the needle tip of the probe pin when performing the apex detection processing.

4. The inspection device of the semiconductor integrated circuit according to claim 3, wherein the margin vector 6 is calculated based on the shape of the probe pin, an angle of the probe pin with respect to the inspection pad, and pressure that the probe card is pressed to the inspection pad when detecting the conduction.

5. The inspection device of the semiconductor integrated circuit according to claim 3, wherein the control unit presses the probe pin to the inspection pad in initial coordinates to detect conduction, then moves the probe pin in a direction that moves away from the center of the inspection pad by (φ+δx) along with x axis and (φ+δy) along with y axis, detects conduction in each of the coordinates after the movement, and sets the initial coordinates to the apex coordinates when no conduction is detected.

6. The inspection device of the semiconductor integrated circuit according to claim 3, wherein the inspection pad used in the apex detection processing has a relatively small margin vector among the plurality of pads of the semiconductor integrated circuit.

7. The inspection device of the semiconductor integrated circuit according to claim 3, wherein the inspection pad used in the apex detection processing is located around the center among the plurality of pads of the semiconductor integrated circuit.

8. The inspection device of the semiconductor integrated circuit according to claim 1, wherein the control unit performs the conduction inspection for one semiconductor integrated circuit, moves coordinates of the probe card based on arrangement information of the semiconductor integrated circuit so that the probe card is provided over another semiconductor integrated circuit, performs inspection of conduction of another semiconductor integrated circuit, so as to perform inspection of conduction of a plurality of semiconductor integrated circuits.

9. The inspection device of the semiconductor integrated circuit according to claim 8, wherein the control unit performs processing for detecting the apex for the plurality of pads, and adjusts an angle of the probe card or a lateral position of the probe card based on the detection result.

10. The inspection device of the semiconductor integrated circuit according to claim 8, wherein, when adjusting an angle of the probe card or a lateral position of the probe card, the control unit at least sets pads located at both ends of the semiconductor integrated circuit to the inspection pads which are subjected to the apex detection processing, and detects each apex.

11. The inspection device of the semiconductor integrated circuit according to claim 1, wherein the control unit moves the probe pin in a direction away from a center of the inspection pad by (φ+δx) along with x axis and (φ+δy) along with y axis based on a margin vector δ(δx,δy) and a diameter φ of the needle tip of the probe pin when performing the apex detection processing, the margin vector being a deviation amount of the needle tip of the probe pin when the probe pin is pressed to the inspection pad, detects conduction in each coordinate after the movement, determines that the apex detection processing is in failure to repeat detection when conduction is detected in the point after the movement, and performs the apex detection processing on another apex of the inspection pad when the detection processing is failed for a plurality of times.

12. The inspection device of the semiconductor integrated circuit according to claim 1, wherein the semiconductor inspection device measures signals input to or output from the inspection pad by an IC tester connected to the probe card through the probe pin when performing inspection of conduction of the inspection pad, to perform inspection of the operation of the semiconductor integrated circuit.

13. An inspection method of a semiconductor integrated circuit comprising:
storing a shape of a plurality of pads connected to a plurality of terminals of the semiconductor integrated circuit and an arrangement of the semiconductor integrated circuit in a storage unit;
controlling a drive unit to move a probe card back and forth and from side to side, the probe card including a plurality of probe pins, the respective probe pins corresponding to a plurality of inspection pads connected to the plurality of terminals of the semiconductor integrated circuit, the inspection pad being a target to be inspected among the plurality of pads;
performing an apex detection processing pressing the probe pin to the semiconductor integrated circuit, detecting a position of the probe pin where conduction is detected and another position of the probe pin where conduction is not detected, and calculating coordinates of one apex of the inspection pad from detected positions, the inspection pads being a target to be inspected among the plurality of pads; and
calculating central coordinates of the inspection pad from information of the shape of the inspection pad based on the coordinates of the apex of the inspection pad; and
controlling the drive unit to press the probe pin to the calculated central coordinates of the inspection pad to perform inspection.
